(19) United States
(12) Patent Application Publication
(10) Pub. No.: US 2026/0271541 A1
(43) Pub. Date: Sep. 10, 2026

(54) DISPLAY DEVICE AND ELECTRONIC DEVICE INCLUDING THE SAME

(71) Applicant: Samsung Display Co., LTD., Yongin-si (KR)

(72) Inventors: Won Woo CHOI, Yongin-si (KR); Jong Seok KIM, Yongin-si (KR); Seong Jun LEE, Yongin-si (KR)

(21) Appl. No.: 19/533,602

(22) Filed: Feb. 9, 2026

(30) Foreign Application Priority Data
Mar. 4, 2025 (KR) 10-2025-0027574
Apr. 10, 2025 (KR) 10-2025-0046611

(51) Int. Cl. H10K 59/122

(52) U.S. Cl. CPC H10K 59/122

(57) ABSTRACT

A display device includes a main display area including a main emission area, and a sub-display area including a sub-emission area and a transmission area. Each of the main emission area and the sub-emission area includes a plurality of emission areas. The emission area includes a pixel electrode, a first common electrode disposed on the pixel electrode, and a light-emitting layer disposed between the pixel electrode and the first common electrode. The transmission area includes a first transmission area and a second transmission area surrounding the first transmission area. The first transmission area includes a replacement pattern, and the second transmission area includes a second common electrode including the same material as that of the first common electrode. The replacement pattern and the second common electrode are disposed in the same layer.

### CROSS-REFERENCE TO RELATED APPLICATIONS

This application claims priority to Korean Patent Application No. 10-2025-0027574, filed on Mar. 4, 2025, and Korean Patent Application No. 10-2025-0046611, filed on Apr. 10, 2025, and all the benefits accruing therefrom under 35 U.S.C. §119, the contents of which in their entirety is are herein incorporated by reference.

### BACKGROUND

### Field

The specification relates to a display device and an electronic device including the same.

### Description of the Related Art

Electroluminescence displays may be divided into inorganic light-emitting displays and organic light-emitting displays depending on the material of a light-emitting layer. An active matrix type organic light-emitting display includes an organic light-emitting diode (“OLED”) that emits light by itself and has advantages of fast response speed, high luminous efficiency, high luminance and wide viewing angle. In the organic light-emitting display, the OLED is formed in each pixel. The organic light-emitting display not only has fast response speed and excellent luminous efficiency, luminance and viewing angle, but also has excellent contrast ratio and color gamut because it may express a black gray level as complete black.

### SUMMARY

Features of the specification provide a display device with improved display quality.

However, features of the specification are not restricted to the one set forth herein. The above and other features of the specification will become more apparent to one of ordinary skill in the art to which the specification pertains by referencing the detailed description of the specification given below.

In an embodiment of the disclosure, a display device includes a main display area including a main emission area, and a sub-display area including a sub-emission area and a transmission area. Each of the main emission area and the sub-emission area includes a plurality of emission areas. An emission area of the plurality of emission areas includes a pixel electrode, a first common electrode disposed on the pixel electrode, and a light-emitting layer disposed between the pixel electrode and the first common electrode. The transmission area includes a first transmission area and a second transmission area surrounding the first transmission area. The first transmission area includes a replacement pattern, and the second transmission area includes a second common electrode including the same material as that of the first common electrode. The replacement pattern and the second common electrode are disposed in the same layer.

In an embodiment, the replacement pattern may include a carbon-based material.

In an embodiment, the main display area and the sub-display area may further include a first pixel defining layer disposed on a passivation layer and configured to cover an end of the pixel electrode to define the emission area. The second transmission area may be disposed on the passivation layer and may further include a second pixel defining layer including the same material as that of the first pixel defining layer. The second common electrode may be disposed on the second pixel defining layer.

In an embodiment, the transmission area may be defined by the second pixel defining layer and may further include an opening area overlapping the first transmission area in a thickness direction.

In an embodiment, the main display area and the sub-display area may further include a first spacer disposed on the first pixel defining layer, and the second transmission area may further include a second spacer disposed on the second pixel defining layer and including the same material as that of the first spacer.

In an embodiment, the first transmission area may further include a second spacer disposed on the passivation layer.

In an embodiment, the replacement pattern and the second common electrode may be disposed on the second spacer.

In an embodiment, the main display area and the sub-display area may further include a first spacer disposed on the first pixel defining layer, the second transmission area may further include a second spacer disposed on the second pixel defining layer and including the same material as that of the first spacer, the first transmission area may further include a second spacer disposed on the passivation layer, and the second spacer of each of the first and second transmission areas may be disposed in the opening area.

In an embodiment, the first spacer may include the same material as that of the passivation layer.

In an embodiment, the second spacer may include the same material as that of the passivation layer.

In an embodiment, the opening area may be defined by an upper surface of the passivation layer and side surfaces of the second pixel defining layer, and a first height from the upper surface of the passivation layer to an upper surface of the second spacer in the first transmission area may be equal to a second height from the upper surface of the passivation layer to the upper surface of the second spacer in the second transmission area.

In an embodiment, in the second transmission area, the second pixel defining layer may be disposed on the upper surface of the passivation layer.

In an embodiment, a thickness of the second spacer disposed in the first transmission area may be different from a thickness of the second spacer disposed in the second transmission area.

In an embodiment, a thickness of the replacement pattern and a thickness of the second common electrode may be substantially equal.

In an embodiment, the transmission area may further include an encapsulation layer disposed on the replacement pattern and the second common electrode.

In an embodiment, the encapsulation layer may include a first encapsulation layer including an inorganic insulating material and a second encapsulation layer disposed on the first encapsulation layer and including a polymer-based material.

In an embodiments of the disclosure, a display device may include a processor providing an image signal, a display module receiving the image signal from the processor and displaying an image, and a power module supplying power to the display module. The display module includes a main display area including a main emission area, and a sub-display area including a sub-emission area and a transmission area. Each of the main emission area and the sub-emission area includes a plurality of emission areas. An emission area of the plurality of emission areas includes a pixel electrode, a first common electrode disposed on the pixel electrode, and a light-emitting layer disposed between the pixel electrode and the first common electrode. The transmission area includes a first transmission area and a second transmission area surrounding the first transmission area. The first transmission area includes a replacement pattern, and the second transmission area includes a second common electrode including the same material as that of the first common electrode. The replacement pattern and the second common electrode are disposed in the same layer.

In an embodiment, the main display area and the sub-display area may further include a first pixel defining layer disposed on a passivation layer and configured to cover an end of the pixel electrode to define the emission area, the second transmission area may be disposed on the passivation layer and may further include a second pixel defining layer including the same material as that of the first pixel defining layer, and the second common electrode may be disposed on the second pixel defining layer.

In an embodiment, the main display area and the sub-display area may further include a first spacer disposed on the first pixel defining layer, the second transmission area may further include a second spacer disposed on the second pixel defining layer and including the same material as that of the first spacer, the first transmission area may further include a second spacer disposed on the passivation layer, and the first spacer may include the same material as that of the passivation layer.

In an embodiment, a thickness of the second spacer disposed in the first transmission area may be different from a thickness of the second spacer disposed in the second transmission area.

A display device in an embodiment of the specification may improve transmittance characteristics by placing a replacement pattern and, at the same time, may reduce a gap between a first phase difference and a second phase difference by placing a second spacer in an opening area defined by a second pixel defining layer. Therefore, the display quality of the display device may be ensured, and the transmittance characteristics of a sub-display area may be improved.

### BRIEF DESCRIPTION OF THE DRAWINGS

These and/or other features will become apparent and more readily appreciated from the following description of the embodiments, taken in conjunction with the accompanying drawings in which:

FIG. 1 is a perspective view of an embodiment of a display device;

FIG. 2 is a plan view of an embodiment of the display device;

FIG. 3 is a cross-sectional view taken along line X1-X1’ of FIG. 2;

FIG. 4 is an enlarged view of area A of FIG. 2;

FIG. 5 is a plan view of an embodiment of a sub-display area;

FIG. 6 is a plan view illustrating an embodiment of a light-blocking layer, a first color filter layer, a second color filter layer, and a third color filter layer in a main display pixel;

FIG. 7 is a plan view of an embodiment of the light-blocking layer in the main display pixel;

FIG. 8 is a plan view of an embodiment of the first color filter layer in the main display pixel;

FIG. 9 is a plan view of an embodiment of the second color filter layer in the main display pixel;

FIG. 10 is a plan view of an embodiment of the third color filter layer in the main display pixel;

FIG. 11 is a cross-sectional view taken along line X2-X2’ of FIG. 6;

FIG. 12 is a partial enlarged view of area J of FIG. 5;

FIG. 13 is a cross-sectional view taken along line X3-X3’ of FIG. 12;

FIG. 14 is a cross-sectional view taken along line X4-X4’ of FIG. 12;

FIG. 15 is a partial enlarged view of area K of FIG. 14;

FIG. 16 is a cross-sectional view illustrating a first comparative example;

FIG. 17 is a cross-sectional view illustrating a second comparative example;

FIG. 18 is a diagram for comparing phase change amounts between a first transmission area and a second transmission area;

FIG. 19 is a block diagram of an embodiment of an electronic device; and

FIG. 20 is a schematic diagram of embodiments of electronic devices.

### DETAILED DESCRIPTION

The advantages and features of the embodiments disclosed herein, and methods of achieving them, will become apparent upon reference to the embodiments described in detail with accompanying drawings. However, the disclosure according to the disclosure is not limited to the embodiments disclosed herein, but will be embodied in many different forms, and these embodiments are provided merely to make the disclosure complete and to fully inform one of ordinary skill in the art to which the disclosure according to the disclosure belongs, and the disclosure according to the disclosure is defined by the scope of the claims.

References to an element or layer as being “on” another element or layer include both cases in which another layer or element is directly on top of or interposed between other elements. Throughout this specification, like reference numerals refer to like components. The shapes, sizes, proportions, angles, numbers, etc. disclosed in the drawings to illustrate embodiments are exemplary and are not intended to be limiting to those shown herein.

Although first, second, and the like are used to describe various components, the components are not limited by these terms. Thus, a first component referred to herein may also be a second component within the technical idea of the disclosure.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments will be described below with reference to the accompanying drawings. Configurations that function substantially the same between embodiments are given the same drawing designation and repeated description is omitted.

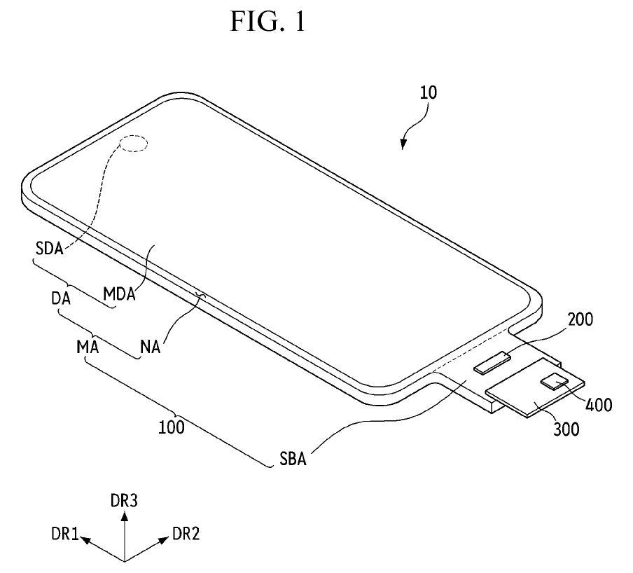

FIG. 1 is a perspective view of an embodiment of a display device 10.

Referring to FIG. 1, the display device 10 is a device for displaying moving images or still images. The display device 10 may be used as a display screen in portable electronic devices such as mobile phones, smartphones, tablet personal computers (“PCs”), smart watches, watch phones, mobile communication terminals, electronic notebooks, electronic books, portable multimedia players (“PMPs”), navigation devices and ultra-mobile PCs (“UMPCs”), as well as in various products such as televisions, notebook computers, monitors, billboards and Internet of things (“IoT”) devices.

The display device 10 may be a light-emitting display device such as an organic light-emitting display device including an organic light-emitting diode, a quantum dot light-emitting display device including a quantum dot light-emitting layer, an inorganic light-emitting display device including an inorganic semiconductor, or a micro- or nano-light-emitting display device using a micro- or nano-light-emitting diode. An embodiment in which the display device 10 is an organic light-emitting display device will be described below, but the type of the display device 10 is not restricted to an organic light-emitting display device.

In an embodiment, the display device 10 may be formed flat. In an embodiment, the display device 10 may be formed substantially flat in a plan view defined by a first direction DR1 and a second direction DR2 and may have a selected thickness (or height) in a third direction DR3, for example. In an embodiment, the display device 10 may include a curved portion in at least one part such as an edge area. In an alternative embodiment, the display device 10 may be flexible so that it may be bent, curved, folded, or rolled.

In an embodiment, the first direction DR1 may be a lengthwise direction, a column direction or a vertical direction of an image display surface of the display device 10, and the second direction DR2 may be a direction intersecting the first direction DR1, e.g., may be a widthwise direction, a row direction or a horizontal direction. The third direction DR3 may be a thickness direction or a height direction of the display device 10.

The display device 10 may include a display panel 100, a driver 200, a circuit board 300, and a touch driver 400.

The display panel 100 may include a main area MA including a display area DA where an image is displayed and a sub-area SBA disposed at a side of the main area MA.

The main area MA may include the display area DA and a non-display area NA around the display area DA. The display area DA may be disposed in the center of the main area MA and may occupy most of the main area MA. The non-display area NA may be disposed at edges of the main area MA and may contact the sub-area SBA.

The display area DA may be an area where pixels are arranged and where an image is displayed by the pixels. In an embodiment, sensing patterns (e.g., touch electrodes) for detecting a touch input or the like may be further provided in the display area DA, and the display area DA may include a sensing area where a touch input is detected by the sensing patterns.

In an embodiment, the display area DA may be shaped like a substantially quadrangular plane, e.g., a substantially rectangular plane having long sides in the first direction DR1 and short sides in the second direction DR2. Each corner where a long side and a short side of the display area DA meet may be rounded or right-angled. The shape of the display area DA may vary depending on embodiments. In an embodiment, the display area DA may also have a non-quadrangular polygonal shape, a circular shape, or an oval shape, for example.

The display area DA may include a main display area MDA and a sub-display area SDA. The sub-display area SDA is an area where components for adding various functions to the display device 10 are placed. The sub-display area SDA may correspond to a component area.

The non-display area NA may be disposed immediately around the display area DA. The non-display area NA may surround the display area DA. An embedded circuit may be disposed in the non-display area NA. In an embodiment, an embedded circuit such as a scan driving circuit may be disposed in the non-display area NA on one side (e.g., a left or right side) or opposite sides of the display area DA, for example.

The sub-area SBA may be disposed on a side of the main area MA. In an embodiment, the sub-area SBA may be an area protruding from a side of the main area MA in the first direction DR1, for example. In an embodiment, the sub-area SBA may protrude from a lower end of the main area MA in the first direction DR1, for example. In an embodiment, the sub-area SBA may be narrower than the main area MA. In an embodiment, the sub-area SBA may be narrower than the main area MA in the second direction DR2, for example.

Lines and pads may be disposed in the sub-area SBA. In an embodiment, lines and pads, which are connected to pixels and/or an embedded circuit disposed in the main area MA and the driver 200 and/or the circuit board 300 disposed in the sub-area SBA, may be disposed in the sub-area SBA, for example. In the description of embodiments, the term “connection” may mean electrical connection and/or physical connection.

In an embodiment, the driver 200 (e.g., a display driving circuit) may be disposed (e.g., mounted) in the sub-area SBA. The circuit board 300 may be disposed on a portion of the sub-area SBA.

The driver 200 may include a data driving circuit for driving pixels. In an embodiment, the driver 200 may be formed as an integrated circuit and placed in the sub-area SBA. In an embodiment, the driver 200 may be placed on the circuit board 300 on the sub-area SBA or may be placed on another circuit board which is connected to the display panel 100 through the circuit board 300.

The circuit board 300 may be placed on a portion of the sub-area SBA. In an embodiment, the circuit board 300 may be bonded onto pads disposed in a portion (e.g., a lower edge) of the sub-area SBA and may supply or transmit power voltages and driving signals for driving the display panel 100 to the display panel 100, for example. In an embodiment, the circuit board 300 may supply input image data (e.g., digital image data), driving signals including timing signals, and driving voltages to the display panel 100, for example. The circuit board 300 may be, but is not restricted to, a flexible printed circuit board (“FPCB”), a printed circuit board (“PCB”), or a flexible film such as a chip on film (“COF”).

The touch driver 400 may be disposed (e.g., mounted) on the circuit board 300. The touch driver 400 may be connected to a touch sensing unit of the display panel 100. The touch driver 400 may supply a touch driving signal to a plurality of touch electrodes of the touch sensing unit and sense the amount of change in capacitance between the touch electrodes. In an embodiment, the touch driving signal may be a pulse signal having a selected frequency, for example. The touch driver 400 may calculate whether an input has occurred and coordinates of the input based on the amount of change in capacitance between the touch electrodes. The touch driver 400 may be formed as an integrated circuit.

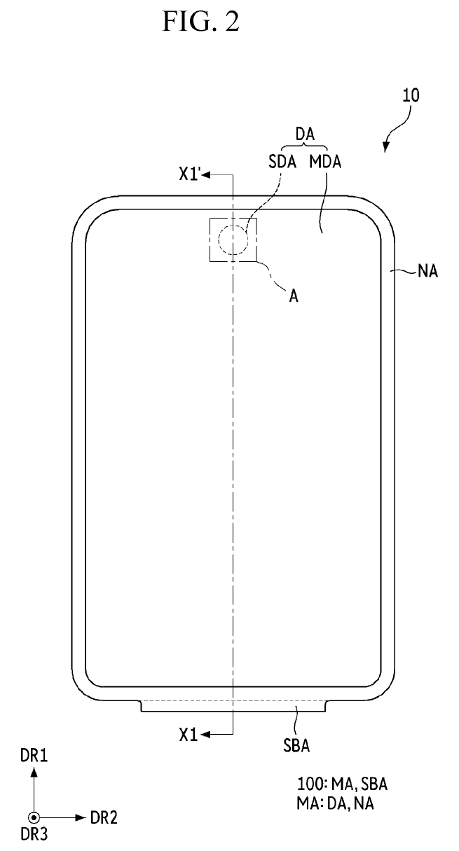

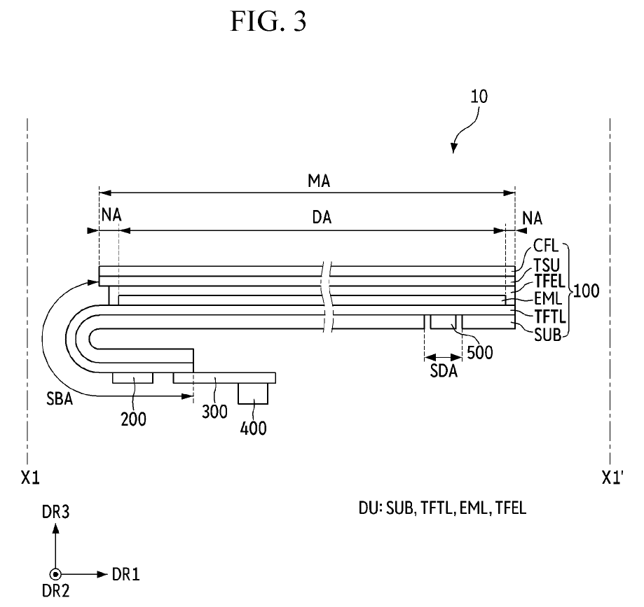

FIG. 2 is a plan view of an embodiment of the display device 10. FIG. 3 is a cross-sectional view taken along line X1-X1’ of FIG. 2.

FIG. 1 illustrates the display device 10 a state in which the display device 10 is unfolded without being bent, and FIGS. 2 and 3 illustrate the display device 10 in a state in which the display device 10 is bent in the sub-area SBA. FIG. 1 illustrates the display device 10 in a state in which the sub-area SBA is unfolded to lie side by side with the main area MA, and FIGS. 2 and 3 illustrate the display device 10 in a state in which a portion of the sub-area SBA is bent.

Referring to FIGS. 2 and 3, the display panel 100 may include a substrate SUB including the main area MA and the sub-area SBA and a circuit layer TFTL, a light-emitting element layer EML, an encapsulation layer TFEL, a touch sensing layer TSU and a color filter layer CFL sequentially stacked on the substrate SUB. The circuit layer TFTL may be disposed on the substrate SUB in the main area MA and the sub-area SBA. The light-emitting element layer EML and the encapsulation layer TFEL may be disposed on a portion of the substrate SUB and the circuit layer TFTL. In an embodiment, the light-emitting element layer EML and the encapsulation layer TFEL may be disposed in the main area MA, for example.

In an embodiment, the display device 10 may further include additional elements disposed on the display panel 100. In an embodiment, the display device 10 may further include at least one of a polarizing layer and a protective layer (e.g., a window) disposed on the encapsulation layer TFEL, for example. The polarizing layer and/or the protective layer may be manufactured integrally with the display panel 100 or may be manufactured separately from the display panel 100 and then attached to the display panel 100 by an adhesive layer or the like.

The substrate SUB may include an insulating material such as polymer resin. In an embodiment, the substrate SUB may include polyimide or another insulating material. The substrate SUB may be a flexible substrate that may be bent, folded, or rolled, for example. In an alternative embodiment, the substrate SUB may include an insulating material such as glass.

The circuit layer TFTL may include pixel circuits and lines. In an embodiment, the circuit layer TFTL may include circuit elements (e.g., pixel transistors and a capacitor) constituting a pixel circuit of each pixel and lines connected to the pixels, for example. In an embodiment, the circuit layer TFTL may further include circuit elements constituting an embedded circuit, such as a scan driving circuit, and lines connected to the embedded circuit.

The light-emitting element layer EML may include light-emitting elements disposed in emission areas of pixels. In an embodiment, each of the pixels may include at least one light-emitting element and a pixel circuit connected to the light-emitting element, for example. Each of the pixels may be disposed in a pixel area including an emission area where a light-emitting element is disposed and a pixel circuit area where a pixel circuit is disposed. The emission area and pixel circuit area of each pixel may overlap each other, but the disclosure is not limited to this case.

In the description of embodiments, the circuit layer TFTL and the light-emitting element layer EML are described as being separate from each other. However, the disclosure is not limited to this case. In an embodiment, the circuit layer TFTL and the light-emitting element layer EML may also be integrated with each other, for example.

The encapsulation layer TFEL may cover the light-emitting element layer EML and extend to the non-display area NA to contact the circuit layer TFTL. In an embodiment, the encapsulation layer TFEL may have a multilayer structure including at least two inorganic encapsulation layers overlapping each other and at least one organic encapsulation layer disposed between the inorganic encapsulation layers.

The touch sensing layer TSU may be disposed on the encapsulation layer TFEL. The touch sensing layer TSU may include a plurality of touch electrodes for sensing a user’s touch in a capacitive manner and touch lines connecting the touch electrodes and the touch driver 400. In an embodiment, the touch sensing layer TSU may sense a user’s touch in a mutual capacitance manner or a self-capacitance manner, for example.

In an embodiment, the touch sensing layer TSU may be disposed on a separate substrate placed on the display panel 100. In this case, the substrate supporting the touch sensing layer TSU may be a base member that encapsulates the display panel 100.

The touch electrodes of the touch sensing layer TSU may be disposed in a touch sensor area overlapping the display area DA. The touch lines of the touch sensing layer TSU may be disposed in a touch peripheral area overlapping the non-display area NA.

In some embodiments, the display device 10 may further include an optical device 500. The optical device 500 may be placed in the sub-display area SDA. The optical device 500 may emit or receive light in an infrared, ultraviolet, or visible light band. In an embodiment, the optical device 500 may be an optical sensor that senses light incident on the display device 10, such as a proximity sensor, an illumination sensor, and a camera sensor or an image sensor, for example.

The color filter layer CFL may be disposed on the touch sensing layer TSU. The color filter layer CFL may include a plurality of color filters corresponding to a plurality of emission areas, respectively. Each of the color filters may selectively transmit light of a predetermined wavelength and block or absorb light of other wavelengths. The color filter layer CFL may absorb a portion of light coming from the outside of the display device 10 to reduce reflected light caused by the external light. Therefore, the color filter layer CFL may prevent color distortion caused by reflection of the external light.

The color filter layer CFL may be directly disposed on the touch sensing layer TSU. Accordingly, the display device 10 may not desire a separate substrate for the color filter layer CFL. Therefore, the display panel 100 may have a relatively small thickness.

In an embodiment, the display panel 100 may be bent in a bending area. The bending area may be a portion of the sub-area SBA and may be spaced apart from the main area MA.

The substrate SUB and the circuit layer TFTL may be bent in the bending area corresponding to a portion of the sub-area SBA. Accordingly, a bezel area perceived by a user as the non-display area NA may be reduced or minimized. In an embodiment, the substrate SUB, the circuit layer TFTL, the light-emitting element layer EML and the encapsulation layer TFEL may be collectively referred to as a display layer DU.

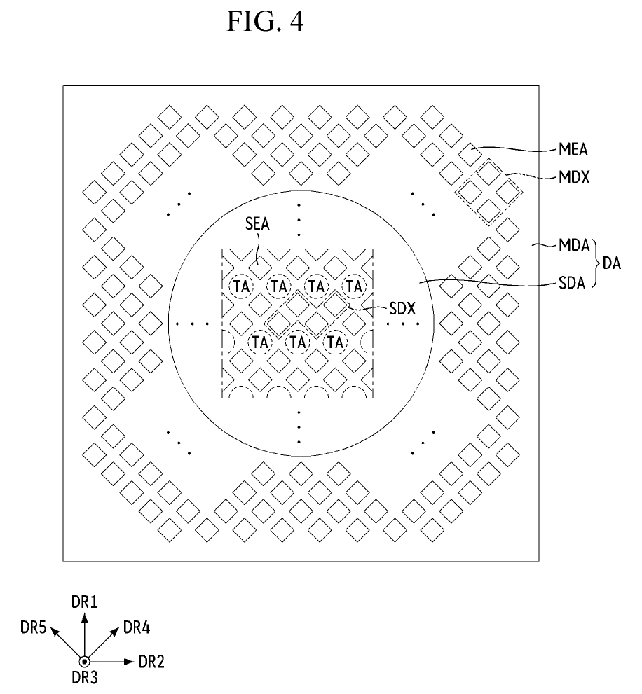

FIG. 4 is an enlarged view of area A of FIG. 2.

FIG. 4 illustrates the arrangement of pixels MDX and SDX in the sub-display area SDA and the main display area MDA around the sub-display area SDA in the display area DA of the display device 10.

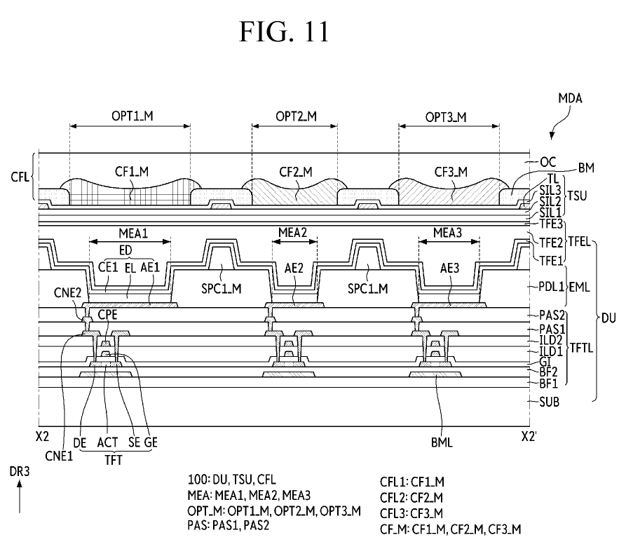

Referring to FIG. 4, the display area DA may include the main display area MDA and the sub-display area SDA. The sub-display area SDA may be an area where a component is placed under the substrate SUB of the display device 10. A plurality of main display pixels MDX may be disposed in the main display area MDA, and a plurality of sub-display pixels SDX may be disposed in the sub-display area SDA. Each of the main display pixels MDX may include one or more main emission areas MEA, and each of the sub-display pixels SDX may include one or more sub-emission areas SEA. A light-emitting element ED (refer to FIG. 11) may be disposed in each of the emission areas MEA and SEA to emit light.

In the main display area MDA, a plurality of light-emitting elements ED emitting light and pixel circuits electrically connected to the light-emitting elements ED to apply signals for light emission of the light-emitting elements ED may be disposed. The main display area MDA may be an area in which the light-emitting elements ED and the pixel circuits are disposed in a predetermined way. In the main display area MDA, each of the light-emitting elements ED may constitute a main emission area MEA, and a plurality of main emission areas MEA may constitute one main display pixel MDX. In an embodiment, four main emission areas MEA may constitute one main display pixel MDX, for example. That is, one main display pixel MDX may include four main emission areas MEA, and four main emission areas MEA may constitute one main display pixel MDX to express a white gray level. However, the number of main emission areas MEA included in a main display pixel MDX is not limited to four.

In some embodiments, the main display pixels MDX in the main display area MDA may be arranged in a fourth direction DR4 and a fifth direction DR5 which are diagonal directions between the first direction DR1 and the second direction DR2. In addition, the main emission areas MEA of the main display pixels MDX may be arranged in the fourth direction DR4 and the fifth direction DR5.

In the sub-display area SDA, light-emitting elements ED emitting light may also be disposed. Each of the light-emitting elements ED may constitute a sub-emission area SEA, and a plurality of sub-emission areas SEA may constitute one sub-display pixel SDX. The sub-display area SDA may be an area that overlaps an optical device as a component disposed on a back surface of the substrate SUB of the display panel 100, for example. Unlike the main display area MDA, the sub-display area SDA may have a structure that takes light transmittance into account.

A sub-display pixel SDX formed by a plurality of sub-emission areas SEA of the sub-display area SDA may have a different arrangement from a main display pixel MDX, but embodiments of the specification are not limited to this case.

In some embodiments, the sub-display pixels SDX in the sub-display area SDA may be arranged in the fourth direction DR4 and the fifth direction DR5 which are diagonal directions between the first direction DR1 and the second direction DR2. In addition, the sub-emission areas SEA of the sub-display pixels SDX may be arranged in the fourth direction DR4 and the fifth direction DR5.

The sub-display area SDA may further include transmission areas TA which transmit light. Each of the transmission areas TA is an area that passes light incident on the display panel 100.

The transmission areas TA may be disposed next (adjacent) to the sub-emission areas SEA. The transmission areas TA may not overlap the sub-emission areas SEA. The transmission areas TA may be surrounded by the sub-emission areas SEA.

The transmission areas TA may be arranged in the first direction DR1. The sub-emission areas SEA may be arranged not only between the first direction DR1 and the second direction DR2 of the transmission areas TA, but also between the fourth direction DR4 and the fifth direction DR5.

Due to the transmission areas TA, the number of sub-emission areas SEA per unit area in the sub-display area SDA may be different from the number of main-emission areas MEA per unit area in the main display area MDA. In an embodiment, the number of sub-emission areas SEA per unit area in the sub-display area SDA may be smaller than the number of main-emission areas MEA per unit area in the main display area MDA, for example.

In addition, due to the transmission areas TA, a ratio of the area of the sub-emission areas SEA to the area of the sub-display area SDA may be different from a ratio of the area of the main emission areas MEA to the area of the main display area MDA. In an embodiment, the ratio of the area of the sub-emission areas SEA to the area of the sub-display area SDA may be smaller than the ratio of the area of the main emission areas MEA to the area of the main display area MDA, for example.

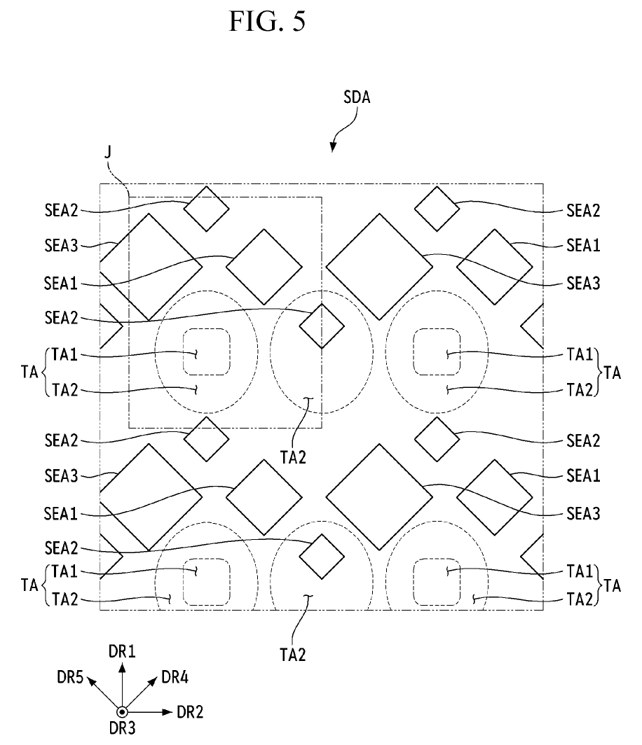

FIG. 5 is a plan view of an embodiment of a sub-display area SDA.

Referring to FIG. 5, the sub-display area SDA may include a plurality of sub-display pixels. The sub-display pixels may be arranged in the fourth direction DR4 and the fifth direction DR5. The sub-display pixels may be repeatedly arranged throughout the sub-display area SDA as illustrated in the drawing.

Each of the sub-display pixels may include a plurality of sub-emission areas SEA. In an embodiment, each of the sub-display pixels may include a first sub-emission area SEA1, a second sub-emission area SEA2, and a third sub-emission area SEA3, for example. However, the number of sub-emission areas SEA included in a sub-display pixel is not limited to three and may be variously changed.

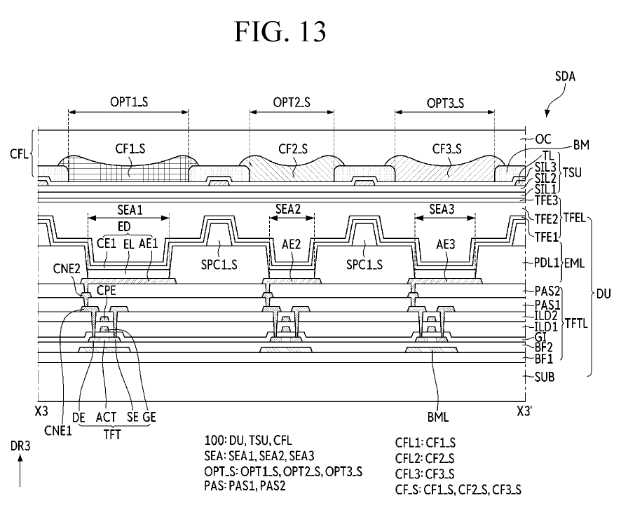

One sub-display pixel may include one or more light-emitting elements ED (refer to FIG. 13). One or more light-emitting elements ED included in one sub-display pixel may emit light of the same color or different colors. In an embodiment, a light-emitting element ED disposed in the first sub-emission area SEA1 may emit first light which is red light, a light-emitting element ED disposed in the second sub-emission area SEA2 may emit second light which is green light, and a light-emitting element ED disposed in the third sub-emission area SEA3 may emit third light which is blue light, for example. However, embodiments of the specification are not limited to this example.

In an embodiment, the sub-display area SDA may include transmission areas TA. The transmission areas TA may be arranged in the second direction DR2. The transmission areas TA may include a first transmission area TA1 in which a replacement pattern is disposed and a second transmission area TA2 in which a second common electrode is disposed. The second transmission area TA2 may surround the first transmission area TA1.

Any one of the transmission areas TA may surround a second sub-emission area SEA2. In an embodiment, a first sub-emission area SEA1, an independently existing second sub-emission area SEA2, a third sub-emission area SEA3, a second sub-emission area SEA2 surrounded by a second transmission area TA2, and a first transmission area TA1 and a second transmission area TA2 spaced apart from the independently existing second sub-emission area SEA2 in the first direction DR1 may form one unit. The one unit may be repeated in the sub-display area SDA.

An embodiment may include a first pixel defining layer defining main emission areas and sub-emission areas SEA1, SEA2 and SEA3, a first spacer disposed on the first pixel defining layer, and a first common electrode disposed on the first pixel defining layer and the first spacer. In other words, a pixel defining layer defining the main emission areas and the sub-emission areas SEA1, SEA2 and SEA3 and a spacer disposed on the pixel defining layer may be the first pixel defining layer and the first spacer, respectively.

The transmission areas TA may be defined by a light-blocking layer as will be described later. An embodiment may include a second pixel defining layer disposed in the transmission areas TA, a second spacer disposed on the second pixel defining layer, and a second common electrode disposed on the second pixel defining layer and the second spacer. In other words, a pixel defining layer and a spacer disposed in the transmission areas TA defined by the light-blocking layer may be the second pixel defining layer and the second spacer, respectively.

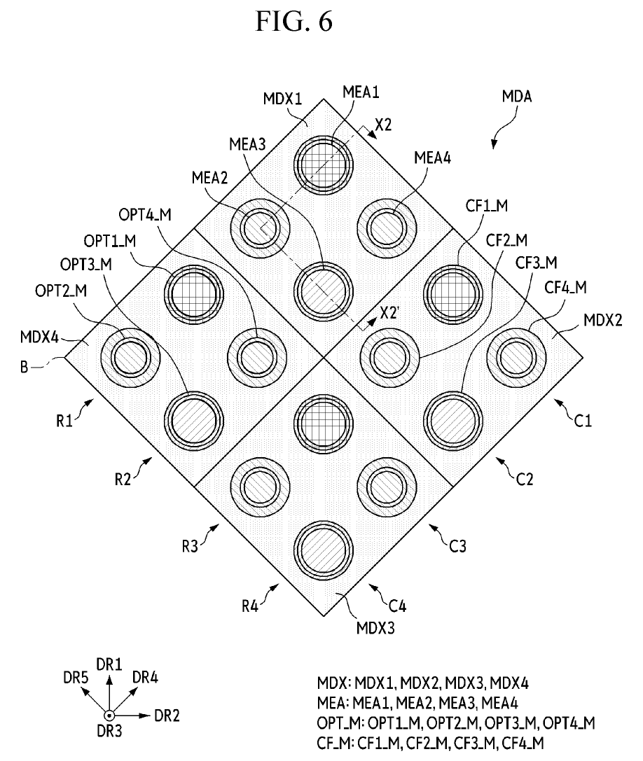

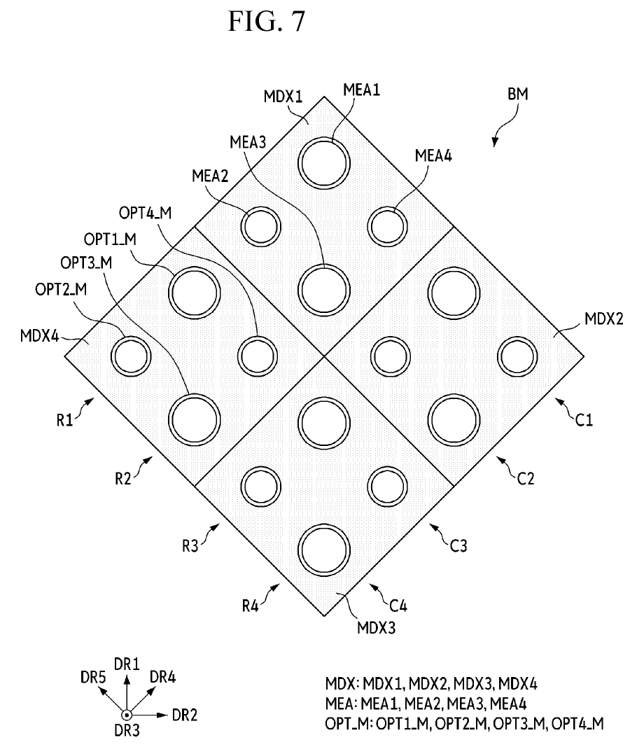

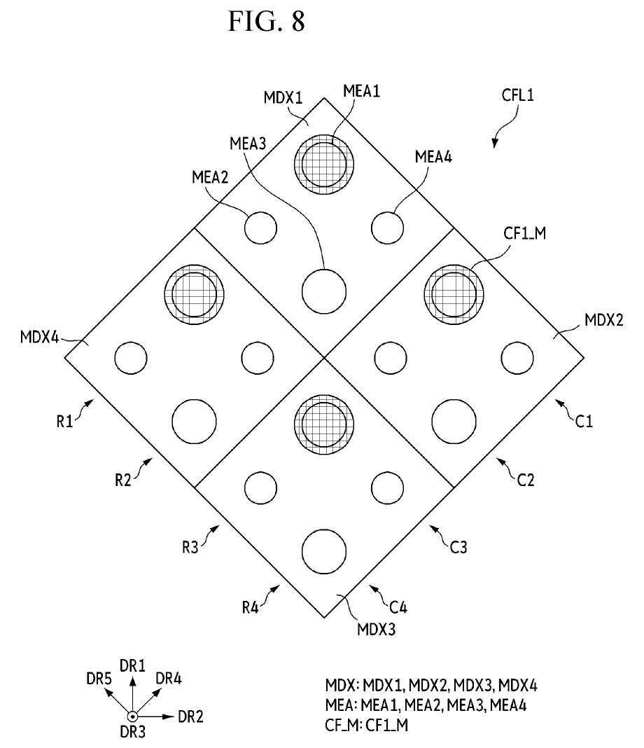

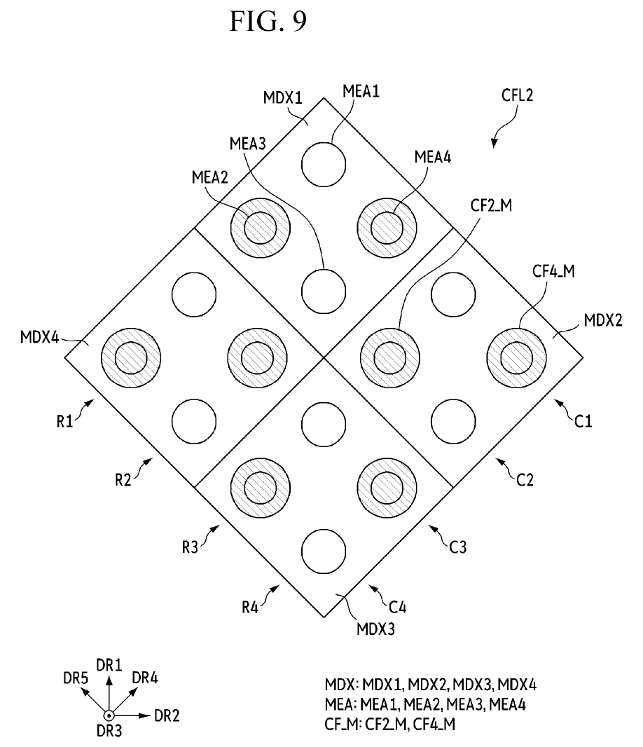

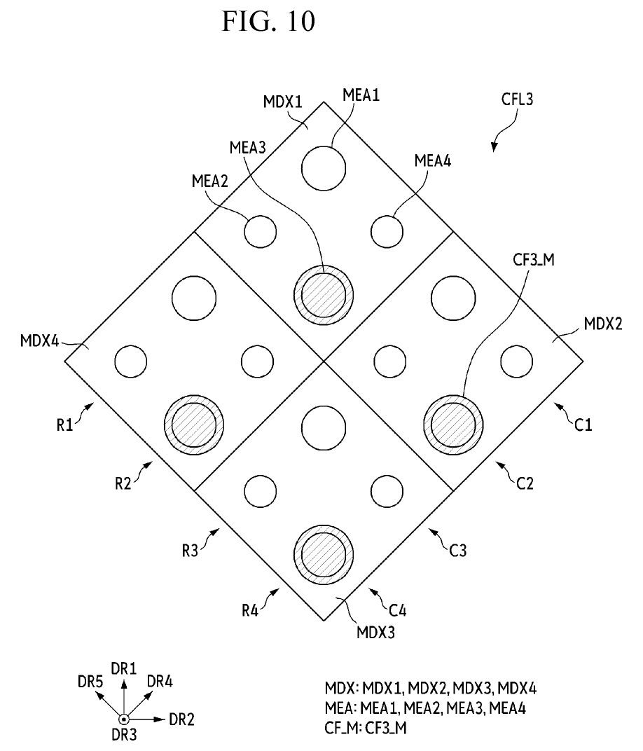

FIG. 6 is a plan view illustrating an embodiment of a light-blocking layer, a first color filter layer, a second color filter layer, and a third color filter layer in a main display pixel. FIG. 7 is a plan view of an embodiment of the light-blocking layer in the main display pixel. FIG. 8 is a plan view of an embodiment of the first color filter layer in the main display pixel. FIG. 9 is a plan view of an embodiment of the second color filter layer in the main display pixel. FIG. 10 is a plan view of an embodiment of the third color filter layer in the main display pixel.

Referring to FIGS. 6 through 10, the main display area MDA may include a plurality of main display pixels MDX. In an embodiment, the main display area MDA may include a first main display pixel MDX1, a second main display pixel MDX2, a third main display pixel MDX3, and a fourth main display pixel MDX4, for example.

The main display pixels MDX may be arranged in the fourth direction DR4 and the fifth direction DR5. In an embodiment, the first main display pixel MDX1 and the second main display pixel MDX2 may be arranged in the fifth direction DR5, the second main display pixel MDX2 and the third main display pixel MDX3 may be arranged in the fourth direction DR4, the third main display pixel MDX3 and the fourth main display pixel MDX4 may be arranged in the fifth direction DR5, and the fourth main display pixel MDX4 and the first main display pixel MDX1 may be arranged in the fourth direction DR4, for example. The first through fourth main display pixels MDX1 through MDX4 may be repeatedly arranged throughout the main display area MDA as illustrated.

Each of the main display pixels MDX may include a plurality of main emission areas MEA. In an embodiment, each of the main display pixels MDX may include a first main emission area MEA1, a second main emission area MEA2, a third main emission area MEA3, and a fourth main emission area MEA4, for example. The fourth main emission area MEA4 may be substantially the same as the second main emission area MEA2. However, the number of main emission areas MEA included in a main display pixel MDX is not limited to four and may be variously changed.

One main display pixel MDX may include one or more light-emitting elements ED (refer to FIG. 11). One or more light-emitting elements ED included in one main display pixel MDX may emit light of the same color or different colors. In an embodiment, a light-emitting element ED disposed in the first main emission area MEA1 may emit first light which is red light, a light-emitting element ED disposed in the second main emission area MEA2 may emit second light which is green light, and a light-emitting element ED disposed in the third main emission area MEA3 may emit third light which is blue light, for example. A light-emitting element ED disposed in the fourth main emission area MEA4 may emit the second light which is green light. However, the disclosure is not limited to this example.

A main emission area MEA may be an area where a light-emitting layer EL (refer to FIG. 11) overlaps a pixel electrode AE1, AE2 or AE3 (refer to FIG. 11). In an embodiment, an opening of a first pixel defining layer PDL1 (refer to FIG. 11) may correspond to the main emission area MEA, for example. In an embodiment, the main emission areas MEA may be respectively defined by a plurality of openings of the first pixel defining layer PDL1 of the light-emitting element layer EML (refer to FIG. 11), for example.

The first main emission area MEA1 may be defined by a first opening of the first pixel defining layer PDL1 which overlaps a first pixel electrode AE1 (refer to FIG. 11), the second main emission area MEA2 may be defined by a second opening of the first pixel defining layer PDL1 which overlaps a second pixel electrode AE2 (refer to FIG. 11), and the third main emission area MEA3 may be defined by a third opening of the first pixel defining layer PDL1 which overlaps the third pixel electrode AE3 (refer to FIG. 11). Although not illustrated in the drawings, the fourth main emission area MEA4 may be defined by a fourth opening of the first pixel defining layer PDL1 which overlaps a fourth pixel electrode.

The main emission areas MEA may be arranged in a pentile type, e.g., a diamond pentile type. In an embodiment, the first main emission area MEA1 and the third main emission area MEA3 may be spaced apart from each other in the first direction DR1 and may be alternately and repeatedly arranged in the first direction DR1 and the second direction DR2, for example. The second main emission area MEA2 and the fourth main emission area MEA4 may be spaced apart from each other in the second direction DR2. The second main emission area MEA2 and the fourth main emission area MEA4 may be spaced apart from a neighboring (adjacent) first main emission area MEA1 and a neighboring (adjacent) third main emission area MEA3 in the fourth direction DR4 or the fifth direction DR5. The second main emission area MEA2 and the fourth main emission area MEA4 may be alternately and repeatedly arranged along the first direction DR1 and the second direction DR2. The second main emission area MEA2 and the first main emission area MEA1 or the fourth main emission area MEA4 and the third main emission area MEA3 may be alternately and repeatedly arranged along the fourth direction DR4 or the fifth direction DR5.

In a first diagonal column C1, the first main emission area MEA1 and the fourth main emission area MEA4 of the first main display pixel MDX1 and the first main emission area MEA1 and the fourth main emission area MEA4 of the second main display pixel MDX2 may be arranged in the fifth direction DR5. In a second diagonal column C2, the second main emission area MEA2 and the third main emission area MEA3 of the first main display pixel MDX1 and the second main emission area MEA2 and the third main emission area MEA3 of the second main display pixel MDX2 may be arranged in the fifth direction DR5. In a third diagonal column C3, the first main emission area MEA1 and the fourth main emission area MEA4 of the fourth main display pixel MDX4 and the first main emission area MEA1 and the fourth main emission area MEA4 of the third main display pixel MDX3 may be arranged in the fifth direction DR5. In a fourth diagonal column C4, the second main emission area MEA2 and the third main emission area MEA3 of the fourth main display pixel MDX4 and the second main emission area MEA2 and the third main emission area MEA3 of the third main display pixel MDX3 may be arranged in the fifth direction DR5.

In a first diagonal row R1, the first main emission area MEA1 and the second main emission area MEA2 of the first main display pixel MDX1 and the first main emission area MEA1 and the second main emission area MEA2 of the fourth main display pixel MDX4 may be arranged in the fourth direction DR4. In a second diagonal row R2, the fourth main emission area MEA4 and the third main emission area MEA3 of the first main display pixel MDX1 and the fourth main emission area MEA4 and the third main emission area MEA3 of the fourth main display pixel MDX4 may be arranged in the fourth direction DR4. In a third diagonal row R3, the first main emission area MEA1 and the second main emission area MEA2 of the second main display pixel MDX2 and the first main emission area MEA1 and the second main emission area MEA2 of the third main display pixel MDX3 may be arranged in the fourth direction DR4. In a fourth diagonal row R4, the fourth main emission area MEA4 and the third main emission area MEA3 of the second main display pixel MDX2 and the fourth main emission area MEA4 and the third main emission area MEA3 of the third main display pixel MDX3 may be arranged in the fourth direction DR4.

In an embodiment, the areas or sizes of the first through fourth main emission areas MEA1 through MEA4 may be different from each other. As illustrated, the area of the first main emission area MEA1 may be larger than the areas of the second main emission area MEA2, the third main emission area MEA3 and the fourth main emission area MEA4, and the area of the third main emission area MEA3 may be larger than the areas of the second main emission area MEA2 and the fourth main emission area MEA4. The intensity of light emitted from each main emission area MEA may vary depending on the area of the main emission area MEA, and the color of a screen displayed on the display device 10 may be controlled by adjusting the area of each main emission area MEA. In the illustrated embodiment, the area of the first main emission area MEA1 is the largest. However, the disclosure is not limited to this case. The size of each main emission area MEA and the area of emission area of each main emission area MEA may be freely adjusted according to the screen color desired by the display device 10. In addition, the area of each main emission area MEA may be related to light efficiency, the life of a light-emitting element ED, etc. and may be in a trade-off relationship with reflection of external light. The area of each main emission area MEA may be adjusted in consideration of the above factors.

In the drawings, each of the main emission areas MEA has a circular planar shape. However, the disclosure is not limited to this case.

The display device 10 may include a light-blocking layer BM and a first color filter layer CFL1, a second color filter layer CFL2 and a third color filter layer CFL3 stacked on the light-blocking layer BM.

The light-blocking layer BM may be disposed over the entirety of the display area DA. In an embodiment, the light-blocking layer BM may be disposed over the main display area MDA and the sub-display area SDA, for example.

A plurality of main openings OPT_M defined in the main display area MDA and corresponding to the main emission areas MEA, respectively, may be defined in the light-blocking layer BM. In other words, the main openings OPT_M may be defined by the light-blocking layer BM. The light-blocking layer BM may cover the main display area MDA except for areas in which the main openings OPT_M are defined in the main display area MDA. The main openings OPT_M of the light-blocking layer BM may be areas from which light emitted from light-emitting elements ED corresponding to the main emission areas MEA are output.

The main openings OPT_M may include a first main opening OPT1_M overlapping each first main emission area MEA1, a second main opening OPT2_M overlapping each second main emission area MEA2, a third main opening OPT3_M overlapping each third main emission area MEA3, and a fourth main opening OPT4_M overlapping each fourth main emission area MEA4.

The planar area of each of the main openings OPT_M may be larger than the planar area of each of the main emission areas MEA. In an embodiment, the planar area of the first main opening OPT1_M may be larger than the planar area of the first main emission area MEA1, the planar area of the second main opening OPT2_M may be larger than the planar area of the second main emission area MEA2, the planar area of the third main opening OPT3_M may be larger than the planar area of the third main emission area MEA3, and the planar area of the fourth main opening OPT4_M may be larger than the planar area of the fourth main emission area MEA4, for example.

The first color filter layer CFL1 may be disposed on the light-blocking layer BM. The second color filter layer CFL2 may be disposed on the first color filter layer CFL1. The third color filter layer CFL3 may be disposed on the second color filter layer CFL2.

The first color filter layer CFL1 may include a first main color portion CF1_M disposed in the main display area MDA, the second color filter layer CFL2 may include a second main color portion CF2_M and a fourth main color portion CF4_M disposed in the main display area MDA, and the third color filter layer CFL3 may include a third main color portion CF3_M disposed in the main display area MDA. The first through fourth main color portions CF1_M through CF4_M may be included in main color portions CF_M.

A main color portion CF_M may include a colorant, such as a dye or pigment, that absorbs light of wavelengths other than light of a predetermined wavelength and may be placed to correspond to the color of light emitted from a light-emitting element ED. In an embodiment, the first main color portion CF1_M may be a red color filter that overlaps the first main emission area MEA1 and transmits only the first light which is red light, for example. The second main color portion CF2_M may be a green color filter that overlaps the second main emission area MEA2 and transmits only the second light which is green light. The third main color portion CF3_M may be a blue color filter that overlaps the third main emission area MEA3 and transmits only the third light which is blue light. The fourth main color portion CF4_M may be a green color filter that overlaps the fourth main emission area MEA4 and transmits only the second light which is green light.

The main color portions CF_M may be arranged to correspond to the main emission areas MEA, respectively. In an embodiment, the first main color portion CF1_M may overlap the first main emission area MEA1, the second main color portion CF2_M may overlap the second main emission area MEA2, the third main color portion CF3_M may overlap the third main emission area MEA3, and the fourth main color portion CF4_M may overlap the fourth main emission area MEA4, for example.

Like the main emission areas MEA, the main color portions CF_M may be arranged in a pentile type, e.g., a diamond pentile type. In an embodiment, the first main color portion CF1_M and the third main color portion CF3_M may be spaced apart from each other in the first direction DR1 and may be alternately and repeatedly arranged in the first direction DR1 and the second direction DR2, for example. The second main color portion CF2_M and the fourth main color portion CF4_M may be spaced apart from each other in the second direction DR2. The second main color portion CF2_M and the fourth main color portion CF4_M may be spaced apart from a neighboring (adjacent) first main color portion CF1_M and a neighboring (adjacent) third main color portion CF3_M in the fourth direction DR4 or the fifth direction DR5. The second main color portion CF2_M and the fourth main color portion CF4_M may be alternately and repeatedly arranged along the first direction DR1 and the second direction DR2. The second main color portion CF2_M and the first main color portion CF1_M or the fourth main color portion CF4_M and the third main color portion CF3_M may be alternately and repeatedly arranged along the fourth direction DR4 or the fifth direction DR5.

The main color portions CF_M may have different sizes or areas in a plan view. As described above, the main emission areas MEA may have different sizes or areas. Accordingly, the main color portions CF_M may also have different sizes or areas in a plan view. In an embodiment, the size or area of the first main color portion CF1_M may be larger than the sizes or areas of the second main color portion CF2_M, the third main color portion CF3_M, and the fourth main color portion CF4_M, for example. In addition, the size or area of the third main color portion CF3_M may be larger than the sizes or areas of the second main color portion CF2_M and the fourth main color portion CF4_M.

The planar area of each of the main color portions CF_M may be larger than the planar area of each of the main emission areas MEA. In an embodiment, the planar area of the first main color portion CF1_M may be larger than the planar area of the first main emission area MEA1, the planar area of the second main color portion CF2_M may be larger than the planar area of the second main emission area MEA2, the planar area of the third main color portion CF3_M may be larger than the planar area of the third main emission area MEA3, and the planar area of the fourth main color portion CF4_M may be larger than the planar area of the fourth main emission area MEA4, for example.

The main color portions CF_M may be arranged to correspond to the main openings OPT_M of the light-blocking layer BM, respectively. In an embodiment, the first main color portion CF1_M may overlap the first main opening OPT1_M of the light-blocking layer BM, the second main color portion CF2_M may overlap the second main opening OPT2_M of the light-blocking layer BM, the third main color portion CF3_M may overlap the third main opening OPT3_M of the light-blocking layer BM, and the fourth main color portion CF4_M may overlap the fourth main opening OPT4_M of the light-blocking layer BM, for example.

The planar area of each of the main color portions CF_M may be larger than the planar area of each of the main openings OPT_M of the light-blocking layer BM. In an embodiment, the planar area of the first main color portion CF1_M may be larger than the planar area of the first main opening OPT1_M of the light-blocking layer BM, the planar area of the second main color portion CF2_M may be larger than the planar area of the second main opening OPT2_M of the light-blocking layer BM, the planar area of the third main color portion CF3_M may be larger than the planar area of the third main opening OPT3_M of the light-blocking layer BM, and the planar area of the fourth main color portion CF4_M may be larger than the planar area of the fourth main opening OPT4_M of the light-blocking layer BM, for example. Accordingly, the main color portions CF_M may completely cover the main openings OPT_M of the light-blocking layer BM, respectively.

In the drawings, each of the main color portions CF_M has a circular planar shape. However, the disclosure is not limited to this case.

FIG. 11 is a cross-sectional view taken along line X2-X2’ of FIG. 6.

FIG. 11 illustrates a cross-section of the first through third main emission areas MEA1 through MEA3 of the first main display pixel MDX1 in the main display area MDA. It is assumed that the fourth main emission area MEA4 has substantially the same structure as that of the second main emission area MEA2, and thus a repeated description is omitted.

Referring to FIGS. 6 through 11, the display panel 100 of the display device 10 may include a display layer DU, a touch sensing layer TSU, and a color filter layer CFL. The display layer DU may include a substrate SUB, a thin-film transistor layer TFTL, a light-emitting element layer EML, and an encapsulation layer TFEL.

The substrate SUB may be a base substrate or a base member. The substrate SUB may be a flexible substrate that may be bent, folded, rolled, etc. In an embodiment, the substrate SUB may include polymer resin such as polyimide (“PI”), but the disclosure is not restricted to this embodiment, for example. In another embodiment, the substrate SUB may include a glass material or a metal material.

The thin-film transistor layer TFTL may include a first buffer layer BF1, bottom metal layers BML, a second buffer layer BF2, thin-film transistors TFT, a gate insulating layer GI, a first inter-insulating layer ILD1, capacitor electrodes CPE, a second inter-insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BF1 may include an inorganic layer that may prevent penetration of air or moisture. In an embodiment, the first buffer layer BF1 may include a plurality of inorganic layers stacked alternately, for example.

The bottom metal layers BML may be disposed on the first buffer layer BF1. In an embodiment, each of the bottom metal layers BML may be a single layer or a multilayer including any one or more of molybdenum (Mo), aluminum (Al), chromium (Cr), gold (Au), titanium (Ti), nickel (Ni), neodymium (Nd), copper (Cu), and alloys thereof, for example.

The second buffer layer BF2 may cover the first buffer layer BF1 and the bottom metal layers BML. The second buffer layer BF2 may include an inorganic layer that may prevent penetration of air or moisture. In an embodiment, the second buffer layer BF2 may include a plurality of inorganic layers stacked alternately, for example.

The thin-film transistors TFT may be disposed on the second buffer layer BF2 and may form respective pixel circuits of a plurality of pixels. In an embodiment, each of the thin-film transistors TFT may be a driving transistor or a switching transistor of a pixel circuit, for example. Each of the thin-film transistors TFT may include a semiconductor layer ACT, a source electrode SE, a drain electrode DE, and a gate electrode GE.

The semiconductor layer ACT may be disposed on the second buffer layer BF2. The semiconductor layer ACT may overlap a bottom metal layer BML and the gate electrode GE in the thickness direction and may be insulated from the gate electrode GE by the gate insulating layer GI. In portions of the semiconductor layer ACT, the material of the semiconductor layer ACT may be made conductive to form the source electrode SE and the drain electrode DE.

The gate electrode GE may be disposed on the gate insulating layer GI. The gate electrode GE may overlap the semiconductor layer ACT with the gate insulating layer GI. The gate insulating layer GI may be disposed between the gate electrode GE and the semiconductor layer ACT.

The gate insulating layer GI may be disposed on the semiconductor layers ACT. In an embodiment, the gate insulating layer GI may cover the semiconductor layers ACT and the second buffer layer BF2 and may insulate the semiconductor layers ACT from the gate electrodes GE, for example. The gate insulating layer GI may include contact holes through which the first connection electrodes CNE1 pass.

The first inter-insulating layer ILD1 may cover the gate electrodes GE and the gate insulating layer GI. The first inter-insulating layer ILD1 may include contact holes through which the first connection electrodes CNE1 pass. The contact holes of the first inter-insulating layer ILD1 may be connected to the contact holes of the gate insulating layer GI and contact holes of the second inter-insulating layer ILD2.

The capacitor electrodes CPE may be disposed on the first inter-insulating layer ILD1. The capacitor electrodes CPE may overlap the gate electrodes GE in the thickness direction. The capacitor electrodes CPE and the gate electrodes GE may form capacitances.

The second inter-insulating layer ILD2 may cover the capacitor electrodes CPE and the first inter-insulating layer ILD1. The second inter-insulating layer ILD2 may include contact holes through which the first connection electrodes CNE1 pass. The contact holes of the second inter-insulating layer ILD2 may be connected to the contact holes of the first inter-insulating layer ILD1 and the contact holes of the gate insulating layer GI.

The first connection electrodes CNE1 may be disposed on the second inter-insulating layer ILD2. The first connection electrodes CNE1 may electrically connect the drain electrodes DE of the thin-film transistors TFT to the second connection electrodes CNE2. The first connection electrodes CNE1 may be inserted into the contact holes defined in the second inter-insulating layer ILD2, the first inter-insulating layer ILD1, and the gate insulating layer GI to contact the drain electrodes DE of the thin-film transistors TFT.

The first passivation layer PAS1 may cover the first connection electrodes CNE1 and the second inter-insulating layer ILD2. The first passivation layer PAS1 may protect the thin-film transistors TFT. The first passivation layer PAS1 may include contact holes through which the second connection electrodes CNE2 pass.

The second connection electrodes CNE2 may be disposed on the first passivation layer PAS1. The second connection electrodes CNE2 may electrically connect the first connection electrodes CNE1 to pixel electrodes AE1, AE2 and AE3 of light-emitting elements ED. The second connection electrodes CNE2 may be inserted into the contact holes defined in the first passivation layer PAS1 to contact the first connection electrodes CNE1.

The second passivation layer PAS2 may cover the second connection electrodes CNE2 and the first passivation layer PAS1. The second passivation layer PAS2 may include contact holes through which the pixel electrodes AE1, AE2 and AE3 of the light-emitting elements ED pass.

The light-emitting element layer EML may be disposed on the thin-film transistor layer TFTL. The light-emitting element layer EML may include the light-emitting elements ED and a first pixel defining layer PDL1. Each of the light-emitting elements ED may include a pixel electrode AE1, AE2 or AE3, a light-emitting layer EL, and a first common electrode CE1. The first common electrode CE1 may be a common electrode disposed in a plurality of emission areas included in the main emission areas MEA and the sub-emission areas SEA. Therefore, the first common electrode CE1 may be disposed on the first pixel defining layer PDL1 and a first spacer SPC1_M.

The pixel electrodes AE1, AE2 and AE3 may be disposed on the second passivation layer PAS2. Different pixel electrodes AE1, AE2 and AE3 may overlap different openings of the first pixel defining layer PDL1, respectively. Each of the pixel electrodes AE1, AE2 and AE3 may be electrically connected to the drain electrode DE of a thin-film transistor TFT through the first and second connection electrodes CNE1 and CNE2.

The light-emitting layer EL may be disposed on each of the pixel electrodes AE1, AE2 and AE3. In an embodiment, the light-emitting layer EL may be, but is not limited to, an organic light-emitting layer including an organic material, for example. When the light-emitting layer EL is an organic light-emitting layer, when a corresponding thin-film transistor TFT applies a selected voltage to a corresponding pixel electrode AE1, AE2 or AE3 and the first common electrode CE1 of a corresponding light-emitting element ED receives a common voltage or a cathode voltage, holes and electrons may move to the light-emitting layer EL through a hole transporting layer and an electron transporting layer, respectively. Then, the holes and the electrons may be combined with each other in the light-emitting layer EL to emit light.

In an embodiment, the light-emitting layers EL respectively disposed on different pixel electrodes AE1, AE2 and AE3 may emit light of different colors. In an embodiment, a light-emitting layer EL disposed on a first pixel electrode AE1 may emit light of a first color which is red light, a light-emitting layer EL disposed on a second pixel electrode AE2 may emit light of a second color which is green light, and a light-emitting layer EL disposed on a third pixel electrode AE3 may emit light of a third color which is blue light, for example. However, the disclosure is not limited to this example. In an embodiment, the light-emitting layers EL may be provided as one common layer on the different pixel electrodes AE1, AE2 and AE3 and the first pixel defining layer PDL1, or the light-emitting layers EL disposed on the different pixel electrodes AE1, AE2 and AE3 may emit light of the same color. In this case, the display device 10 may further include a color adjustment layer disposed on the light-emitting elements ED.

The first common electrode CE1 may be disposed on the light-emitting layers EL. In an embodiment, the first common electrode CE1 may be implemented as an electrode common to all pixels without being separated for each pixel, for example. The first common electrode CE1 may be disposed on the light-emitting layers EL on the pixel electrodes AE1, AE2 and AE3 and may be disposed on the first pixel defining layer PDL1 in an area excluding the pixel electrodes AE1, AE2 and AE3.

The first common electrode CE1 may receive a common voltage or a low-potential voltage. When the pixel electrodes AE1, AE2 and AE3 receive a voltage corresponding to a data voltage and the first common electrode CE1 receives a low-potential voltage, a potential difference may be formed between the pixel electrodes AE1, AE2 and AE3 and the first common electrode CE1. Accordingly, the light-emitting layers EL may emit light.

The first pixel defining layer PDL1 may include a plurality of openings and may be disposed on the second passivation layer PAS2 and a portion of each of the pixel electrodes AE1, AE2 and AE3. The first pixel defining layer PDL1 may be a pixel defining layer that defines the emission areas included in the main emission areas MEA and the sub-emission areas SEA. Each of the openings of the first pixel defining layer PDL1 may expose a portion of the pixel electrode AE1, AE2 or AE3. As described above, the openings of the first pixel defining layer PDL1 may define the first through third main emission areas MEA1 through MEA3, respectively, and their areas or sizes may be different from each other. The first pixel defining layer PDL1 may separate and insulate the respective pixel electrodes AE1, AE2 and AE3 of the light-emitting elements ED from each other.

The first pixel defining layer PDL1 may include a light-absorbing material to prevent light reflection. In an embodiment, the first pixel defining layer PDL1 may include a polyimide (“PI”)-based binder and a pigment in which red, green and blue are mixed, for example. In an alternative embodiment, the first pixel defining layer PDL1 may include a cardo-based binder resin and a combination of a lactam black pigment and a blue pigment. In an alternative embodiment, the first pixel defining layer PDL1 may include carbon black.

The first spacer SPC1_M _M in the main display area MDA may be disposed on the first pixel defining layer PDL1. The first spacer SPC1_M may be a spacer disposed on the first pixel defining layer PDL1 that defines the emission areas included in the main emission area MEA and the sub-emission area SEA.

The first spacer SPC1_M may support a mask during a process of manufacturing the light-emitting layers EL. The first spacer SPC1_M may include an organic layer such as acryl resin, epoxy resin, phenolic resin, polyamide resin, or polyimide resin.

The encapsulation layer TFEL may be disposed on the first common electrode CE1 and may cover the light-emitting elements ED. The encapsulation layer TFEL may include at least one inorganic layer to prevent oxygen or moisture from penetrating into the light-emitting element layer EML. The encapsulation layer TFEL may include at least one organic layer to protect the light-emitting element layer EML from foreign substances such as dust.

In an embodiment, the encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 disposed between the first encapsulation layer TFE1 and the third encapsulation layer TFE3 may be an organic encapsulation layer.

Each of the first encapsulation layer TFE1 and the third encapsulation layer TFE3 may include one or more inorganic insulating materials. The inorganic insulating materials may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. In embodiments, the polymer-based material may include acrylic resin, epoxy resin, polyimide, and polyethylene. In an embodiment, the second encapsulation layer TFE2 may include acrylic resin such as polymethyl methacrylate or polyacrylic acid, for example. The second encapsulation layer TFE2 may be formed by curing a monomer or applying a polymer.

The touch sensing layer TSU may be disposed on the encapsulation layer TFEL. The touch sensing layer TSU may include a first touch insulating layer SIL1, a second touch insulating layer SIL2, touch electrodes TL, and a third touch insulating layer SIL3.

The first touch insulating layer SIL1 may be disposed on the encapsulation layer TFEL. The first touch insulating layer SIL1 may have insulating and optical functions. The first touch insulating layer SIL1 may include at least one inorganic layer. Optionally, the first touch insulating layer SIL1 may be omitted.

The second touch insulating layer SIL2 may cover the first touch insulating layer SIL1. Although not illustrated in the drawing, touch electrodes TL of another layer may be further disposed on the first touch insulating layer SIL1, and the second touch insulating layer SIL2 may cover the touch electrodes TL. The second touch insulating layer SIL2 may have insulating and optical functions. In an embodiment, the second touch insulating layer SIL2 may be an inorganic layer including at least one of a silicon nitride layer, a silicon oxynitride layer, a silicon oxide layer, a titanium oxide layer, and an aluminum oxide layer, for example.

Some of the touch electrodes TL may be disposed on the second touch insulating layer SIL2. Each of the touch electrodes TL may not overlap the pixel electrodes AE1, AE2 and AE3. Each of the touch electrodes TL may be formed as a single layer of molybdenum (Mo), titanium (Ti), copper (Cu), aluminum (Al) or indium tin oxide (“ITO”) or may be formed as a stacked structure (Ti/Al/Ti) of aluminum and titanium, a stacked structure (“ITO/Al/ITO”) of aluminum and indium tin oxide, an silver-palladium-copper (“APC”) alloy, or a stacked structure (“ITO/APC/ITO”) of an APC alloy and indium tin oxide.

The touch electrodes TL of the touch sensing layer TSU may have a selected line width and overlap a light-blocking layer BM. The light-blocking layer BM may have a width sufficient to completely cover the touch electrodes TL. In some embodiments, a center of each touch electrode TL may be substantially aligned with a center of the light-blocking layer BM. A distance from one side of each touch electrode TL to one side of the light-blocking layer BM may be substantially the same as a distance from an opposite side of the touch electrode TL to an opposite side of the light-blocking layer BM.

The third touch insulating layer SIL3 may cover the touch electrodes TL and the second touch insulating layer SIL2. The third touch insulating layer SIL3 may have insulating and optical functions. The third touch insulating layer SIL3 may include a material exemplified in the description of the second touch insulating layer SIL2.

The color filter layer CFL may include the light-blocking layer BM, main color portions CF_M, and an overcoat layer OC.

The light-blocking layer BM may be disposed on the third touch insulating layer SIL3 of the touch sensing layer TSU. The light-blocking layer BM may overlap conductive lines of the touch electrodes TL. The light-blocking layer BM may overlap the first pixel defining layer PDL1 in the third direction DR3.

The light-blocking layer BM may include a plurality of main openings OPT_M which overlap the main emission areas MEA. In an embodiment, a first main opening OPT1_M may overlap the first main emission area MEA1 in the third direction DR3, a second main opening OPT2_M may overlap the second main emission area MEA2 in the third direction DR3, and a third main opening OPT3_M may overlap the third main emission area MEA3 in the third direction DR3, for example. Although not illustrated in the drawing, a fourth main opening OPT4_M may overlap the fourth main emission area MEA4 in the third direction DR3.

The area or size of each main opening OPT_M may be larger than the area or size of each main emission area MEA. In addition, the area or size of each main opening OPT_M may be larger than the area or size of each opening of the first pixel defining layer PDL1, and light emitted from the light-emitting elements ED may be viewed by a user not only from the front but also from the side of the display device 10.

The light-blocking layer BM may include a light-absorbing material. In an embodiment, the light-blocking layer BM may include an inorganic black pigment or an organic black pigment, for example. The inorganic black pigment may be carbon black, and the organic black pigment may include at least one of lactam black, perylene black and aniline black, but embodiments are not restricted to this example.

The main color portions CF_M of the color filter layer CFL may include a first main color portion CF1_M of a first color filter layer CFL1, a second main color portion CF2_M of a second color filter layer CFL2, and a third main color portion CF3_M of a third color filter layer CFL3. Although not illustrated in the drawing, the main color portions CF_M may further include a fourth main color portion CF4_M of the second color filter layer CFL2.

The main color portions CF_M may be arranged to correspond to the main emission areas MEA, respectively. In an embodiment, the first main color portion CF1_M may overlap the first main emission area MEA1 in the third direction DR3, the second main color portion CF2_M may overlap the second main emission area MEA2 in the third direction DR3, and the third main color portion CF3_M may overlap the third main emission area MEA3 in the third direction DR3, for example.

The main color portions CF_M may be arranged to correspond to the main openings OPT_M of the light-blocking layer BM, respectively. In an embodiment, the first main color portion CF1_M may cover the first main opening OPT1_M, the second main color portion CF2_M may cover the second main opening OPT2_M, and the third main color portion CF3_M may cover the third main opening OPT3_M, for example.

Widths of the main color portions CF_M may be greater than widths of the main openings OPT_M of the light-blocking layer BM. In an embodiment, a width of the first main color portion CF1_M may be greater than a width of the first main opening OPT1_M of the light-blocking layer BM, a width of the second main color portion CF2_M may be greater than a width of the second main opening OPT2_M of the light-blocking layer BM, and a width of the third main color portion CF3_M may be greater than a width of the third main opening OPT3_M of the light-blocking layer BM, for example.

The overcoat layer OC may be disposed on the light-blocking layer BM, the first color filter layer CFL1, the second color filter layer CFL2, and the third color filter layer CFL3. The overcoat layer OC may be disposed over the entirety of the display area DA to flatten an upper surface of the display panel 100. The overcoat layer OC may be a colorless light-transmitting layer that does not have a color in a visible light band. In an embodiment, the overcoat layer OC may include a colorless light-transmitting organic material such as acrylic resin, for example.

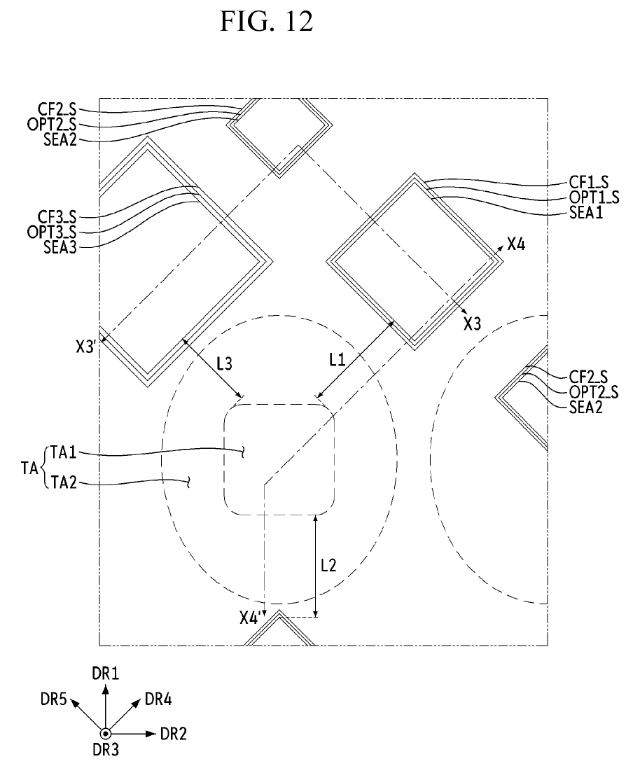

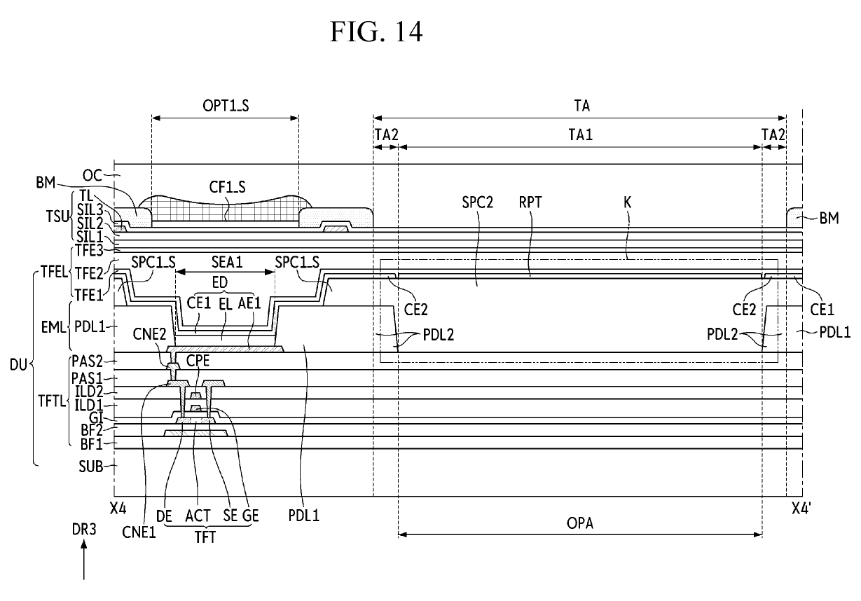

FIG. 12 is a partial enlarged view of area J of FIG. 5. FIG. 13 is a cross-sectional view taken along line X3-X3’ of FIG. 12. FIG. 14 is a cross-sectional view taken along line X4-X4’ of FIG. 12.

Referring to FIGS. 12 through 14, a sub-emission area SEA may be an area where a light-emitting layer EL overlaps a pixel electrode AE1, AE2 or AE3. In an embodiment, an opening of the first pixel defining layer PDL1 may correspond to the sub-emission area SEA, for example. In an embodiment, the sub-emission areas SEA may be respectively defined by a plurality of openings of the first pixel defining layer PDL1 of the light-emitting element layer EML, for example.

A first sub-emission area SEA1 may be defined by a first opening of the first pixel defining layer PDL1 which overlaps a first pixel electrode AE1, a second sub-emission area SEA2 may be defined by a second opening of the first pixel defining layer PDL1 which overlaps a second pixel electrode AE2, and a third sub-emission area SEA3 may be defined by a third opening of the first pixel defining layer PDL1 which overlaps a third pixel electrode AE3.

In an embodiment, the areas or sizes of the first through third sub-emission areas SEA1 through SEA3 may be different from each other. As illustrated, the area of the third sub-emission area SEA3 may be larger than the areas of the first sub-emission area SEA1 and the second sub-emission area SEA2, and the area of the first sub-emission area SEA1 may be larger than the area of the second sub-emission area SEA2. However, the disclosure is not limited to this case. The intensity of light emitted from each sub-emission area SEA may vary depending on the area of the sub-emission area SEA, and the color of the screen may be controlled by adjusting the area of each sub-emission area SEA. The area of each sub-emission area SEA may be related to light efficiency, the life of a light-emitting element ED, etc. and may be in a trade-off relationship with reflection of external light. The area of each sub-emission area SEA may be adjusted in consideration of the above factors.

In the drawings, each of the sub-emission areas SEA has a rhombic planar shape. However, the disclosure is not limited to this case. In addition, although the planar shape of each of the sub-emission areas SEA is illustrated as being different from the planar shape of each of the main emission areas MEA described above, embodiments of the specification are not limited to this case. The shapes may be different as illustrated, but may also be similar in order to secure uniformity in a manufacturing process.

The sub-display area SDA may further include a transmission area TA. As described above, the transmission area TA may include a first transmission area TA1 and a second transmission area TA2. The first transmission area TA1 may be surrounded by the second transmission area TA2. In cross-section, the first transmission area TA1 may be disposed between the second transmission areas TA2.

The first transmission area TA1 may include a replacement pattern, and the second transmission area TA2 may include a second common electrode. The second common electrode may be a common electrode disposed in the transmission area TA defined by a light-blocking layer.

A boundary of the first transmission area TA1 may be spaced apart from the first sub-emission area SEA1 by a first distance L1, from the second sub-emission area SEA2 by a second distance L2, and from the third sub-emission area SEA3 by a third distance L3. A replacement pattern may be placed in the first transmission area TA1. Due to a material included in the replacement pattern, a gas may be released during a process of manufacturing the display device, and thus outgassing may occur. In an embodiment, since the boundary of the first transmission area TA1 is spaced apart from boundaries of the first sub-emission area SEA1, the second sub-emission area SEA2 and the third sub-emission area SEA3 by the first distance L1, the second distance L2 and the third distance L3, respectively, the shrinkage of the emission areas due to the outgassing may be prevented. The boundary of the first transmission area TA1 may be substantially the same as a boundary of the replacement pattern.

The first sub-emission area SEA1, the second sub-emission area SEA2, and the third sub-emission area SEA3 may all have different sizes. In this case, the first distance L1, the second distance L2, and the third distance L3 may all be different. In an embodiment, the smallest of the first distance L1, the second distance L2, and the third distance L3 may be set to a selected value or greater. In an embodiment, the third distance L3 may be the smallest of the first distance L1, the second distance L2, and the third distance L3, for example. When the third distance L3 is formed or designed to be equal to or greater than a selected value, the first distance L1 and the second distance L2 may also be formed or designed to be equal to or greater than the selected value. In an embodiment, the selected value may be 8 micrometers (µm) or greater, 9 µm or greater, 10 µm or greater, 11 µm or greater, 12 µm or greater, or 13 µm or greater.

The display device 10 may include the light-blocking layer BM and the color filter layer CFL disposed on the light-blocking layer BM. As for the sub-display area SDA, the color filter layer CFL will be described without being divided into a plurality of color filter layers. However, the descriptions of the color filter layer CFL disposed in the main display area MDA described above may all be applied to the sub-display area SDA.

The light-blocking layer BM may be disposed over the entirety of the display area DA. In an embodiment, the light-blocking layer BM may be disposed in the main display area MDA and the sub-display area SDA, for example.

A plurality of sub-openings OPT_S defined in the sub-display area SDA and corresponding to the sub-emission areas SEA, respectively, may be defined in the light-blocking layer BM. In other words, the sub-openings OPT_S may be defined by the light-blocking layer BM. The light-blocking layer BM may cover the sub-display area SDA except for areas in which the sub-openings OPT_S are defined in the sub-display area SDA. The sub-openings OPT_S of the light-blocking layer BM may be areas from which light emitted from light-emitting elements ED corresponding to the sub-emission areas SEA are output.

The sub-openings OPT_S may include a first sub-opening OPT1_S overlapping each first sub-emission area SEA1, a second sub-opening OPT2_S overlapping each second sub-emission area SEA2, and a third sub-opening OPT3_S overlapping each third sub-emission area SEA3.

The planar area of each of the sub-openings OPT_S may be larger than the planar area of each of the sub-emission areas SEA. In an embodiment, the planar area of the first sub-opening OPT1_S may be larger than the planar area of the first sub-emission area SEA1, the planar area of the second sub-opening OPT2_S may be larger than the planar area of the second sub-emission area SEA2, and the planar area of the third sub-opening OPT3_S may be larger than the planar area of the third sub-emission area SEA3, for example.

An opening corresponding to each transmission area TA may be defined by the light-blocking layer BM. The openings corresponding to the transmission areas TA may be defined in the first direction DR1.

A plurality of sub-color portions CF_S may be arranged to correspond to the sub-emission areas SEA, respectively. In an embodiment, a first sub-color portion CF1_S may overlap the first sub-emission area SEA1, a second sub-color portion CF2_S may overlap the second sub-emission area SEA2, and a third sub-color portion CF3_S may overlap the third sub-emission area SEA3, for example.

The sub-color portions CF_S may have different sizes or areas in a plan view. As described above, the sub-emission areas SEA may have different sizes or areas. Accordingly, the sub-color portions CF_S may also have different sizes or areas in a plan view. In an embodiment, the size or area of the third sub-color portion CF3_S may be larger than the sizes or areas of the first sub-color portion CF1_S and the second sub-color portion CF2_S, for example. In addition, the size or area of the first sub-color portion CF1_S may be larger than the size or area of the second sub-color portion CF2_S. The size of each of the sub-color portions CF_S may be closely related to the color of the sub-display area SDA according to reflection of external light.

The planar area of each of the sub-color portions CF_S may be larger than the planar area of each of the sub-emission areas SEA. In an embodiment, the planar area of the first sub-color portion CF1_S may be larger than the planar area of the first sub-emission area SEA1, the planar area of the second sub-color portion CF2_S may be larger than the planar area of the second sub-emission area SEA2, and the planar area of the third sub-color portion CF3_S may be larger than the planar area of the third sub-emission area SEA3, for example.

The sub-color portions CF_S may be arranged to correspond to the sub-openings OPT_S of the light-blocking layer BM, respectively. In an embodiment, the first sub-color portion CF1_S may overlap the first sub-opening OPT1_S of the light-blocking layer BM, the second sub-color portion CF2_S may overlap the second sub-opening OPT2_S of the light-blocking layer BM, and the third sub-color portion CF3_S may overlap the third sub-opening OPT3_S of the light-blocking layer BM, for example.

The planar area of each of the sub-color portions CF_S may be larger than the planar area of each of the sub-openings OPT_S of the light-blocking layer BM. In an embodiment, the planar area of the first sub-color portion CF1_S may be larger than the planar area of the first sub-opening OPT1_S of the light-blocking layer BM, the planar area of the second sub-color portion CF2_S may be larger than the planar area of the second sub-opening OPT2_S of the light-blocking layer BM, and the planar area of the third sub-color portion CF3_S may be larger than the planar area of the third sub-opening OPT3_S of the light-blocking layer BM, for example. Accordingly, the sub-color portions CF_S may completely cover the sub-openings OPT_S of the light-blocking layer BM, respectively.

In the drawings, each of the sub-color portions CF_S has a roughly quadrangular planar shape, but the disclosure is not limited to this case.

In a display device in embodiments of the specification, the structure of a main display pixel and a light-blocking layer disposed in a main display area and the structure of a sub-display pixel and a light-blocking layer disposed in a sub-display area may be substantially the same.

Referring to FIGS. 13 and 14, since the display layer DU and the touch sensing layer TSU have been described above, repeated descriptions thereof will be mostly omitted.

The first pixel defining layer PDL1 may be a pixel defining layer that defines a plurality of emission areas included in the main emission areas MEA and the sub-emission areas SEA.

A first spacer SPC1_S in the sub-display area SDA may be disposed on the first pixel defining layer PDL1. The first spacer SPC1_S may be a spacer disposed on the first pixel defining layer PDL1 that defines the emission areas included in the main emission areas MEA and the sub-emission areas SEA.

The first spacer SPC1_S may support a mask during a process of manufacturing light-emitting layers EL. The first spacer SPC1_S may include an organic layer such as acryl resin, epoxy resin, phenolic resin, polyamide resin, or polyimide resin.

Each of the light-emitting elements ED may include a pixel electrode AE1, AE2 or AE3, a light-emitting layer EL, and a first common electrode CE1. The first common electrode CE1 may be a common electrode disposed in the emission areas included in the main emission areas MEA and the sub-emission areas SEA. Therefore, the first common electrode CE1 may be disposed on the first pixel defining layer PDL1 and the first spacer SPC1_S.

The color filter layer CFL may include the light-blocking layer BM, the sub-color portions CF_S, and the overcoat layer OC.

The light-blocking layer BM may include a plurality of sub-openings OPT_S overlapping the sub-emission areas SEA. In an embodiment, the first sub-opening OPT1_S may overlap the first sub-emission area SEA1 in the third direction DR3, the second sub-opening OPT2_S may overlap the second sub-emission area SEA2 in the third direction DR3, and the third sub-opening OPT3_S may overlap the third sub-emission area SEA3 in the third direction DR3, for example.

The area or size of each sub-opening OPT_S may be larger than the area or size of each sub-emission area SEA. In addition, the area or size of each sub-opening OPT_S may be larger than the area or size of each opening of the first pixel defining layer PDL1, and light emitted from the light-emitting elements ED may be viewed by a user not only from the front but also from the side of the display device 10.

The sub-color portions CF_S of the color filter layer CFL may include the first sub-color portion CF1_S of the first color filter layer CFL1, the second sub-color portion CF2_S of the second color filter layer CFL2, and the third sub-color portion CF3_S of the third color filter layer CFL3.

The sub-color portions CF_S may be arranged to correspond to the sub-emission areas SEA, respectively. In an embodiment, the first sub-color portion CF1_S may overlap the first sub-emission area SEA1 in the third direction DR3, the second sub-color portion CF2_S may overlap the second sub-emission area SEA2 in the third direction DR3, and the third sub-color portion CF3_S may overlap the third sub-emission area SEA3 in the third direction DR3, for example.

The sub-color portions CF_S may be arranged to correspond to the sub-openings OPT_S of the light-blocking layer BM, respectively. In an embodiment, the first sub-color portion CF1_S may cover the first sub-opening OPT1_S, the second sub-color portion CF2_S may cover the second sub-opening OPT2_S, and the third sub-color portion CF3_S may cover the third sub-opening OPT3_S, for example.

Widths of the sub-color portions CF_S may be greater than widths of the sub-openings OPT_S of the light-blocking layer BM. In an embodiment, a width of the first sub-color portion CF1_S may be greater than a width of the first sub-opening OPT1_S of the light-blocking layer BM, a width of the second sub-color portion CF2_S may be greater than a width of the second sub-opening OPT2_S of the light-blocking layer BM, and a width of the third sub-color portion CF3_S may be greater than a width of the third sub-opening OPT3_S of the light-blocking layer BM, for example.

Referring to FIG. 14, a transmission area TA may be defined by the light-blocking layer BM. The light-blocking layer BM may define an opening that defines the transmission area TA. The transmission area TA may be defined as an area between a side surface of any one light-blocking layer BM and a side surface of another light-blocking layer BM.

An embodiment may include a pixel defining layer (PDL1, PDL2) including a first pixel defining layer PDL1 and a second pixel defining layer PDL2, a spacer (SPC1_S, SPC2) including a first spacer SPC1_S and a second spacer SPC2, and a common electrode (CE1, CE2) including a first common electrode CE1 and a second common electrode CE2. As illustrated, the first spacer SPC1_S and the second spacer SPC2, the first pixel defining layer PDL1 and the second pixel defining layer PDL2, and the first common electrode CE1 and the second common electrode CE2 may be physically connected to each other at a boundary of the transmission area TA. The second pixel defining layer PDL2 may include the same material as that of the first pixel defining layer PDL1, the second spacer SPC2 may include the same material as that of the first spacer SPC1_S, and the second common electrode CE2 may include the same material as that of the first common electrode CE1.

The common electrode (CE1, CE2) including the first common electrode CE1 and the second common electrode CE2 may include a material having relatively high transmittance in a top emission structure. In an embodiment, the common electrode (CE1, CE2) may include a transparent conductive material (“TCO”) that may transmit light, such as indium tin oxide (“ITO”) or indium zinc oxide (“IZO”), or a semi-transmissive conductive material such as magnesium (Mg), silver (Ag) or an alloy of Mg and Ag, for example. When the common electrode (CE1, CE2) includes a semi-transmissive conductive material, light output efficiency may be increased by a microcavity.

Since an optical device is placed in the sub-display area SDA, it is desired to form a path for light to come and go. Therefore, a separate transmission area TA may be placed in the sub-display area SDA. In addition, all metal lines placed in the transmission area TA may include a transparent material to allow light to pass through the transmission area TA. In an embodiment, the common electrode (CE1, CE2) needs to be formed using a transparent conductive material, for example.

However, even when a transparent material is used, the intensity of light passing through a metal may be weakened. In addition, when the second common electrode CE2 is placed over the entirety of the transmission area TA, light transmittance and/or pass rate may be reduced.

A display device in an embodiment of the specification divides the transmission area TA into the second transmission area TA2 including the second common electrode CE2 and the first transmission area TA1 including a replacement pattern RPT. The replacement pattern RPT may be disposed in the same layer as the second common electrode CE2. In an embodiment, both the second common electrode CE2 and the replacement pattern RPT may be disposed on the second spacer SPC2, for example.

In other words, the replacement pattern RPT may be a pattern formed in a process of removing the common electrode (CE1, CE2) to improve light transmittance, etc. The common electrode (CE1, CE2) may be formed in common over the entirety of the display area DA including the main display area MDA and the sub-display area SDA. When the common electrode (CE1, CE2) is deposited after the replacement pattern RPT is formed in at least a portion of the transmission area TA, the second common electrode CE2 may not be placed in the first transmission area TA1, and light transmittance, etc. may be improved through the replacement pattern RPT. The replacement pattern RPT may perform the function of suppressing the formation of a metal layer, thereby improving the transmittance characteristics, etc. of the transmission area TA. The common electrode (CE1, CE2) including the first common electrode CE1 and the second common electrode CE2 may be selectively deposited by the replacement pattern RPT.

In an embodiment, the common electrode (CE1, CE2) may include an alloy of magnesium (Mg) and silver (Ag). The replacement pattern RPT may include a carbon-based material. In an alternative embodiment, the replacement pattern RPT may be a compound including a carbon-based material and a fluorine-based material.

In an embodiment, the replacement pattern RPT may include an aromatic hydrocarbon including a carbon-based material. In an alternative embodiment, the replacement pattern RPT may include a deuterated aromatic hydrocarbon.

As described above, the replacement pattern RPT needs to maintain a predetermined distance from the first sub-emission area SEA1, the second sub-emission area SEA2, and the third sub-emission area SEA3. Accordingly, this may prevent the shrinkage of the emission areas due to gas generated during a manufacturing process.

Going back to the previous description, the replacement pattern RPT may be a material that replaces the common electrode (CE1, CE2) to improve characteristics such as transmittance. Therefore, the replacement pattern RPT in the first transmission area TA1 may be disposed in the same layer as the second common electrode CE2 or the first common electrode CE1.

The first transmission area TA1 may be defined by the replacement pattern RPT. In an embodiment, the first transmission area TA1 may be defined by a boundary or side surfaces of the replacement pattern RPT, for example. A boundary between the replacement pattern RPT and the second common electrode CE2 may be formed at a boundary between the first transmission area TA1 and the second transmission area TA2.

In addition, since the second spacer SPC2 is placed in the first transmission area TA1, the second pixel defining layer PDL2 may not be placed in the first transmission area TA1. The first transmission area TA1 may overlap an opening area OPA, which is defined as an area between ends of the second pixel defining layer PDL2, in the third direction DR3. The second spacer SPC2 may be placed in the first transmission area TA1. The second spacer SPC2 may also be placed in the second transmission area TA2. This structure will be described in detail later.

An embodiment may additionally include the first transmission area TA1 in which the replacement pattern RPT is placed to improve transmittance, etc. In addition, the transmission area TA may further include the second transmission area TA2 in which the second common electrode CE2 including a metal material is placed.

The first transmission area TA1 in which the common electrode (CE1, CE2) is not formed may be easily recognized compared with the second transmission area TA2, the sub-emission areas SEA and the main emission areas MEA in which the common electrode (CE1, CE2) is placed. Since the second common electrode CE2 placed in the second transmission area TA2 includes the same material as that of the first common electrode CE1 placed in the sub-emission areas SEA and the main emission areas MEA, all of them are simplified, and only a phase difference of the second transmission area TA2 and a phase difference of the first transmission area TA1 are taken into account.

The first transmission area TA1 may have a first phase difference, and the second transmission area TA2 may have a second phase difference. When a gap between the first phase difference and the second phase difference is relatively large, it means that the first transmission area TA1 is relatively easily recognized in the display device, and therefore, the display quality of the display device is degraded.

The display device in the embodiment of the specification may improve transmittance characteristics by placing the replacement pattern RPT and, at the same time, may reduce the gap between the first phase difference and the second phase difference by placing the second spacer SPC2 in the opening area OPA defined by the second pixel defining layer PDL2. Therefore, the display quality of the display device may be ensured, and the transmittance characteristics of the sub-display area SDA may be improved.

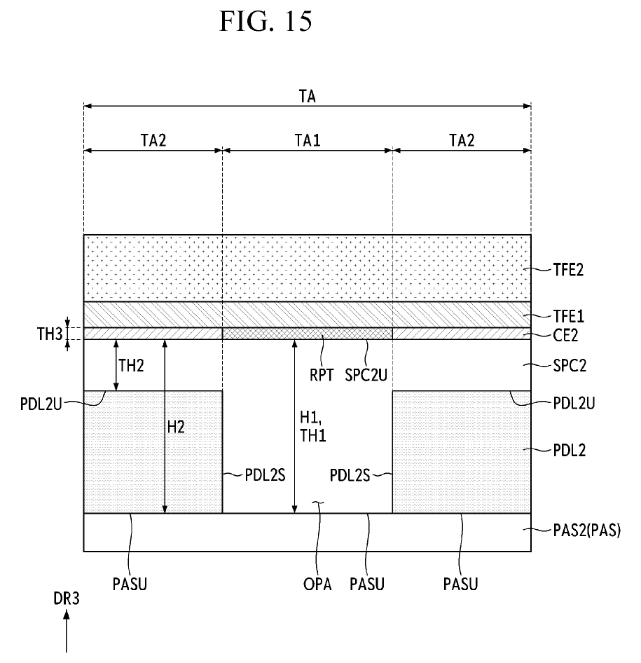

FIG. 15 is a partial enlarged view of area K of FIG. 14. FIG. 15 is also a cross-sectional view illustrating an embodiment of the specification.

Referring to FIG. 15, the second pixel defining layer PDL2 may be disposed on the second passivation layer PAS2 (or a passivation layer PAS). The second pixel defining layer PDL2 may be disposed in the second transmission area TA2. The opening area OPA may be defined by side surfaces PDL2S of the second pixel defining layer PDL2 and an upper surface PASU of the passivation layer PAS. In other words, the second pixel defining layer PDL2 may include the opening area OPA.

The second spacer SPC2 may include the same material as that of the first spacer SPC1_S. In the second transmission area TA2, the second spacer SPC2 may be disposed on the second pixel defining layer PDL2. The second spacer SPC2 disposed in the second transmission area TA2 may be physically connected to the second spacer SPC2 disposed in the first transmission area TA1. The second spacer SPC2 disposed in the first transmission area TA1 may also be disposed in the opening area OPA defined by the second pixel defining layer PDL2.

Both the replacement pattern RPT in the first transmission area TA1 and the second common electrode CE2 in the second transmission area TA2 may be disposed at the same layer. In an embodiment, they may be disposed on the second spacer SPC2, for example.

In an embodiment, the second spacer SPC2 may include the same material as that of the second passivation layer PAS2 (or the passivation layer PAS). Therefore, the second passivation layer PAS2 (or the passivation layer PAS) may include the same material as that of the first spacer SPC1_S.

An encapsulation layer (TFE1, TFE2) may be disposed on the second common electrode CE2 and the replacement pattern RPT. The encapsulation layer (TFE1, TFE2) may include a first encapsulation layer TFE1 and a second encapsulation layer TFE2 disposed on the first encapsulation layer TFE1. The first encapsulation layer TFE1 may include an inorganic insulating material, and the second encapsulation layer TFE2 may include a polymer-based material. In an embodiment, the second encapsulation layer TFE2 may be an organic encapsulation layer, and the first encapsulation layer TFE1 may be an inorganic encapsulation layer, for example.

According to a display device in an embodiment, the second encapsulation layer TFE2 may have a relatively low dielectric constant. Despite the second encapsulation layer TFE2 having a relatively low dielectric constant, the embodiment may improve the display quality of the display device by reducing the gap between the first phase difference and the second phase difference.

The opening area OPA may overlap the first transmission area TA1 in the third direction DR3. The second spacer SPC2 may fill the opening area OPA. The second spacer SPC2 may include the same material as that of the passivation layer PAS.

In an embodiment, a first height H1 may be defined in the first transmission area TA1, and a second height H2 may be defined in the second transmission area TA2. The first height H1 may be a distance from the upper surface PASU of the passivation layer PAS to an upper surface SPC2U of the second spacer SPC2 in the third direction DR3. The second height H2 may be a distance from the upper surface PASU of the passivation layer PAS to the upper surface SPC2U of the second spacer SPC2 in the third direction DR3. The first height H1 and the second height H2 may be substantially equal. The second pixel defining layer PDL2 may be disposed on the upper surface PASU of the passivation layer PAS in the second transmission area TA2.

The second spacer SPC2 disposed in the first transmission area TA1 may have a first thickness TH1, and the second spacer SPC2 disposed in the second transmission area TA2 may have a second thickness TH2. The first thickness TH1 may be a distance from the upper surface PASU of the passivation layer PAS to the upper surface SPC2U of the second spacer SPC2 in the third direction DR3. The second thickness TH2 may be a distance from an upper surface PDL2U of the second pixel defining layer PDL2 to the upper surface SPC2U of the second spacer SPC2 in the third direction DR3. In an embodiment, the first thickness TH1 and the second thickness TH2 may be different. In an embodiment, a difference between the first thickness TH1 and the second thickness TH2 may be substantially equal to a thickness of the second pixel defining layer PDL2, for example.

Since the replacement pattern RPT, instead of the second common electrode CE2, is placed in the first transmission area TA1 to improve transmittance characteristics, etc., other physical properties of the replacement pattern RPT may have to be substantially the same as those of the second common electrode CE2 except for their materials. Therefore, a thickness of the replacement pattern RPT and a thickness of the second common electrode CE2 may be equal, that is, may be a third thickness TH3.

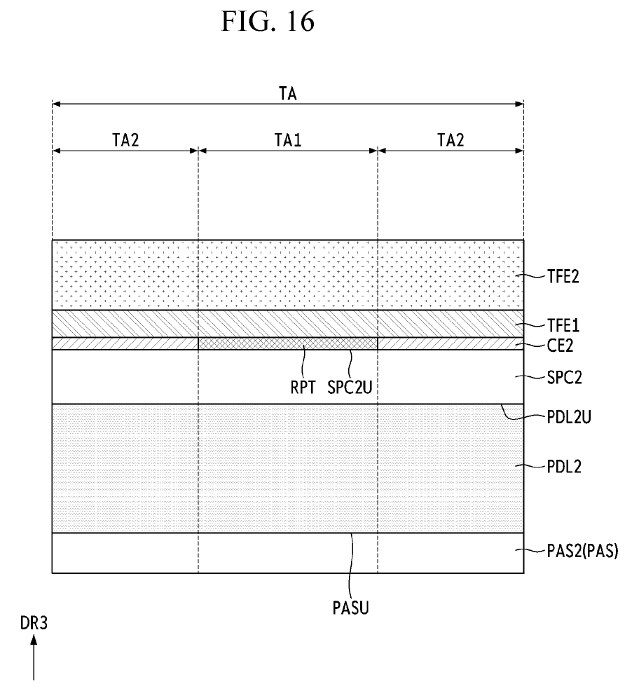

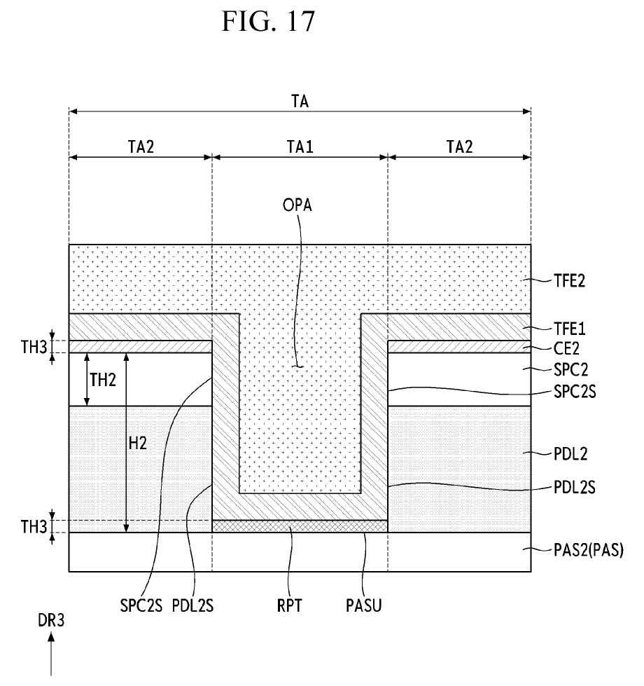

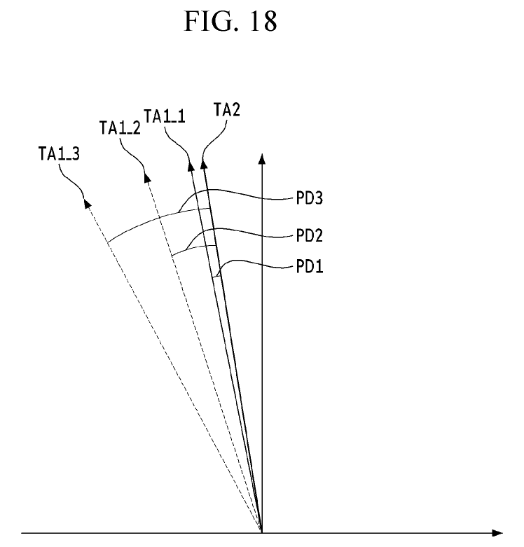

FIG. 16 is a cross-sectional view illustrating a first comparative example. FIG. 17 is a cross-sectional view illustrating a second comparative example. FIG. 18 is a diagram for comparing phase change amounts between a first transmission area and a second transmission area.

The first comparative example is different from the above-described embodiment in that a second pixel defining layer PDL2 does not define an opening area OPA and thus a second spacer SPC2 does not fill the opening area OPA.

In the second comparative example, a second spacer SPC2 is not placed in an opening area OPA. That is, the second spacer SPC2 corresponding to a first transmission area TA1 is completely removed, and then a replacement pattern RPT is placed on an upper surface PASU of a passivation layer PAS. The second comparative example is different from the above-described embodiment in that a first encapsulation layer TFE1 is formed in the opening area OPA, and a second encapsulation layer TFE2 fills the opening area OPA. In an embodiment, the first transmission area TA1 may correspond to an area between side surfaces SPC2S of the second spacer SPC2.

Referring to FIG. 18, the shape and arrangement structure of the second transmission area TA2 are the same in the above-described embodiment, the first comparative example, and the second comparative example. Therefore, the second phase difference of the second transmission area TA2 has a constant value.

A first phase difference TA1_1 of the embodiment is plotted on a graph to have a first phase change amount PD1 from the second phase difference. A first phase difference TA1_2 of the first comparative example is plotted on the graph to have a second phase change amount PD2 from the second phase difference. A first phase difference TA1_3 of the second comparative example is plotted to have a third phase change amount PD3 from the second phase difference.

Referring to the graph, the first phase change amount PD1 is the smallest, and the third phase change amount PD3 is the largest. As described above, the greater the phase change amount corresponding to the gap between the first phase difference and the second phase difference, the higher the probability that the first transmission area TA1 will be recognized in a display device.

A display device in an embodiment of the specification may be applied to various electronic devices. An electronic device in an embodiment includes the above-described display device and may further include modules or devices having other additional functions, in addition to the display device.

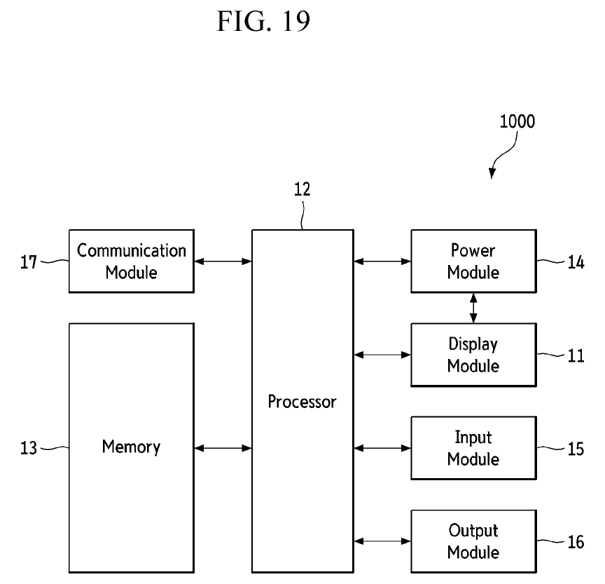

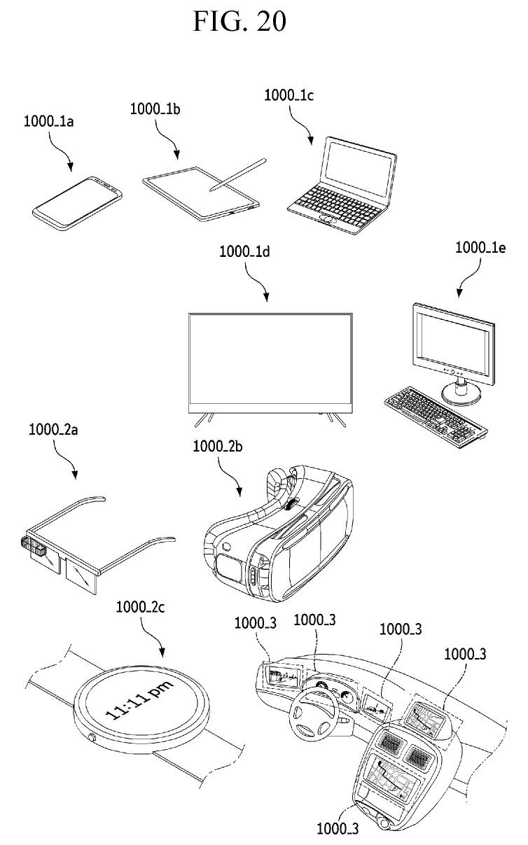

FIG. 19 is a block diagram of an embodiment of an electronic device. FIG. 20 is a schematic diagram of embodiments of electronic devices.

Referring to FIG. 19, an electronic device 1000 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information desired for the operation of the processor 12 or the display module 11. When the processor 12 executes an application stored in the memory 13, an image data signal (also referred to as an image signal) and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may generate power desired for the operation of the electronic device 1000 by converting power supplied by the power supply module.

At least one of the elements of the electronic device 1000 described above may be included in a display device according to the above-described embodiments. In addition, some of individual modules functionally included in one module may be included in the display device, and other modules may be provided separately from the display device. In an embodiment, the display device may include the display module 11, and the processor 12, the memory 13 and the power module 14 may be provided not in the display device but in the form of other devices within the electronic device 1000, for example. In an embodiment, the wireless communication module 17 may transmit/receive a wireless signal to/from other terminal(s) by using Bluetooth^{®} or Wi-Fi.

Referring to FIG. 20, various electronic devices to which a display device in embodiments of the specification is applied may include image display electronic devices such as a smartphone 1000_1a, a tablet PC 1000_1b, a laptop 1000_1c, a television 1000_1d, and a desk monitor 1000_1e. In addition, the various electronic devices to which the display device in the embodiments of the specification is applied may include wearable electronic devices including a display module, such as smart glasses 1000_2a, a head-mounted display 1000_2b and a smart watch 1000_2c, and vehicle electronic devices 1000_3 including a display module, such as a center information display (“CID”) and a room mirror display placed on an instrument cluster, a center fascia and a dashboard of a vehicle.

Although embodiments of the disclosure have been described above with reference to the accompanying drawings, it will be understood by those having ordinary skill in the technical field to which the disclosure belongs that the disclosure may be practiced in other forms without altering the technical idea or essential features of the disclosure. It should therefore be understood that the embodiments described above are exemplary in all respects and are not intended to be limiting.

What is claimed is:

1. A display device comprising:
a main display area comprising a main emission area; and
a sub-display area comprising:
a sub-emission area; and
a transmission area including:
a first transmission area including a replacement pattern; and
a second transmission area surrounding the first transmission area and comprising a second common electrode, each of the main emission area and the sub-emission area comprising:
a plurality of emission areas, an emission area of the plurality of emission areas comprising:
a pixel electrode;
a first common electrode disposed on the pixel electrode; and
a light-emitting layer disposed between the pixel electrode and the first common electrode,
wherein the second common electrode comprises a same material as a material of the first common electrode, and
the replacement pattern and the second common electrode are disposed in a same layer.

2. The display device of claim 1, wherein the replacement pattern comprises a carbon-based material.

3. The display device of claim 1, wherein each of the main display area and the sub-display area further comprises a first pixel defining layer disposed on a passivation layer and covering an end of the pixel electrode to define the emission area, the second transmission area further comprises a second pixel defining layer disposed on the passivation layer and comprising a same material as a material of the first pixel defining layer, and the second common electrode is disposed on the second pixel defining layer.

4. The display device of claim 3, wherein the transmission area further comprises an opening area defined by the second pixel defining layer and overlapping the first transmission area in a thickness direction.

5. The display device of claim 3, wherein each of the main display area and the sub-display area further comprises a first spacer disposed on the first pixel defining layer, and the second transmission area further comprises a second spacer disposed on the second pixel defining layer and comprising a same material as a material of the first spacer.

6. The display device of claim 5, wherein the first transmission area further comprises a second spacer disposed on the passivation layer.

7. The display device of claim 6, wherein the replacement pattern and the second common electrode are disposed on the second spacer.

8. The display device of claim 4, wherein each of the main display area and the sub-display area further comprises a first spacer disposed on the first pixel defining layer, the second transmission area further comprises a second spacer disposed on the second pixel defining layer and comprising a same material as a material of the first spacer, and the first transmission area further comprises a second spacer disposed on the passivation layer, wherein the second spacer of each of the first and second transmission areas is disposed in the opening area.

9. The display device of claim 5, wherein the first spacer comprises a same material as a material of the passivation layer.

10. The display device of claim 5, wherein the second spacer comprises a same material as a material of the passivation layer.

11. The display device of claim 8, wherein the opening area is defined by an upper surface of the passivation layer and side surfaces of the second pixel defining layer, a first height from the upper surface of the passivation layer to an upper surface of the second spacer in the first transmission area is equal to a second height from the upper surface of the passivation layer to the upper surface of the second spacer in the second transmission area.

12. The display device of claim 11, wherein in the second transmission area, the second pixel defining layer is disposed on the upper surface of the passivation layer.

13. The display device of claim 8, wherein a thickness of the second spacer disposed in the first transmission area is different from a thickness of the second spacer disposed in the second transmission area.

14. The display device of claim 1, wherein a thickness of the replacement pattern and a thickness of the second common electrode are substantially equal.

15. The display device of claim 1, wherein the transmission area further comprises an encapsulation layer disposed on the replacement pattern and the second common electrode.

16. The display device of claim 15, wherein the encapsulation layer comprises a first encapsulation layer comprising an inorganic insulating material and a second encapsulation layer disposed on the first encapsulation layer and comprising a polymer-based material.

17. An electronic device comprising:
a processor which provides an image signal;
a display module which receives the image signal from the processor and displaying an image, the display module comprising:
a main display area comprising a main emission area; and
a sub-display area comprising:
a sub-emission area; and
a transmission area comprising:
a first transmission area comprising a replacement pattern; and
a second transmission area surrounding the first transmission area and comprising a second common electrode, each of the main emission area and the sub-emission area comprising:
a plurality of emission areas comprising a pixel electrode;
a first common electrode disposed on the pixel electrode; and
a light-emitting layer disposed between the pixel electrode and the first common electrode, area; and
a power module supplying power to the display module,
wherein
the second common electrode comprises a same material as a material of the first common electrode, and
the replacement pattern and the second common electrode are disposed in a same layer.

18. The electronic device of claim 17, wherein each of the main display area and the sub-display area further comprises a first pixel defining layer disposed on a passivation layer and covering an end of the pixel electrode to define an emission area of the plurality of emission areas, the second transmission area further comprises a second pixel defining layer disposed on the passivation layer and comprising a same material as a material of the first pixel defining layer, and the second common electrode is disposed on the second pixel defining layer.

19. The electronic device of claim 18, wherein each of the main display area and the sub-display area further comprises a first spacer disposed on the first pixel defining layer, the second transmission area further comprises a second spacer disposed on the second pixel defining layer and comprising a same material as a material of the first spacer, and the first transmission area further comprises a second spacer disposed on the passivation layer, wherein the first spacer comprises a same material as a material of the passivation layer.

20. The electronic device of claim 19, wherein a thickness of the second spacer disposed in the first transmission area is different from a thickness of the second spacer disposed in the second transmission area.
